(19) United States
(12) Patent Application Publication
(10) Pub. No.: US 2026/0179664 A1
(43) Pub. Date: Jun. 25, 2026

(54) INTEGRATED CIRCUIT AND METHOD OF OPERATING THE SAME

(71) Applicant: TAIWAN SEMICONDUCTOR MANUFACTURING COMPANY, LTD., Hsinchu (TW)

(72) Inventors: Meng-Sheng CHANG, Hsinchu (TW); Yih WANG, Hsinchu (TW)

(21) Appl. No.: 19/092,746

(22) Filed: Mar. 27, 2025

Related U.S. Application Data
(60) Provisional application No. 63/737,278, filed on Dec. 20, 2024.

(51) Int. Cl. G11C 5/14

(52) U.S. Cl. CPC G11C 5/148

(57) ABSTRACT

An integrated circuit includes a first power rail configured to supply a first supply voltage, a second power rail configured to supply a second supply voltage, a first memory circuit coupled to the first and second power rail, and configured to receive a first control signal, the first or second supply voltage, and a first core circuit. The second supply voltage has a first value or a second value different from the first value. The first memory circuit includes a first header circuit coupled to the second power rail, and configured to supply the second supply voltage to a first node in response to the first control signal, and a first memory cell array coupled to the first header circuit by the first node, and configured to store a first set of data, and to receive the second supply voltage from the first header circuit.

### PRIORITY CLAIM

This application claims the benefit of U.S. Provisional Application No. 63/737,278, filed Dec. 20, 2024, which is incorporated herein by reference in its entirety.

### BACKGROUND

The semiconductor integrated circuit (IC) industry has produced a wide variety of digital devices to address issues in a number of different areas. Some of these digital devices, such as memory macros, are configured for the storage of data. As ICs have become smaller and more complex, the resistance of conductive lines within these digital devices is also changed affecting the operating voltages of these digital devices and overall IC performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a memory circuit, in accordance with some embodiments.

FIG. 2 is a circuit diagram of an integrated circuit, in accordance with some embodiments.

FIG. 3A is a block diagram of a circuit usable in at least FIG. 2 or FIG. 9, in accordance with some embodiments.

FIG. 3B is a block diagram of a circuit usable in at least FIG. 2 or FIG. 9, in accordance with some embodiments.

FIG. 4 is a block diagram of a circuit usable in at least FIG. 2 or FIG. 9, in accordance with some embodiments.

FIGS. 5A-5B are corresponding circuit diagrams of corresponding eFuse circuits, in accordance with some embodiments.

FIG. 6 is a block diagram of a circuit usable in at least FIG. 2 or FIG. 9, in accordance with some embodiments.

FIG. 7 is a timing diagram of waveforms of an integrated circuit, in accordance with some embodiments.

FIG. 8 is a flowchart of a method of operating a circuit, in accordance with some embodiments.

FIG. 9 is a circuit diagram of an integrated circuit, in accordance with some embodiments.

FIG. 10 is a circuit diagram of a level shifter circuit, in accordance with some embodiments.

FIG. 11 is a timing diagram of waveforms of an integrated circuit, in accordance with some embodiments.

FIG. 12 is a flowchart of a method of operating a circuit, in accordance with some embodiments.

FIG. 13 is a schematic view of a controller for generating one or more control signals or voltages, in accordance with some embodiments.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, an integrated circuit includes a first power rail configured to supply a first supply voltage.

In some embodiments, the integrated circuit further includes a second power rail configured to supply a second supply voltage. In some embodiments, the second supply voltage is different from the first supply voltage.

In some embodiments, the integrated circuit further includes a first memory circuit coupled to the first power rail and the second power rail. In some embodiments, the first memory circuit is configured to receive at least one of a first control signal, the first supply voltage or the second supply voltage.

In some embodiments, the integrated circuit further includes a first core circuit coupled to the first memory circuit. In some embodiments, the first core circuit is configured to receive the second supply voltage.

In some embodiments, the first memory circuit includes a first header circuit. In some embodiments, the first header circuit is coupled to the second power rail. In some embodiments, the first header circuit is configured to supply the second supply voltage to at least a first node in response to the first control signal.

In some embodiments, the first memory circuit includes a first memory cell array. In some embodiments, the first memory cell array is coupled to the first header circuit by the first node. In some embodiments, the first memory cell array is configured to store a first set of data, and to receive the second supply voltage from the first header circuit.

In some embodiments, the second supply voltage has a first value or a second value. In some embodiments, the second value is different from the first value.

In some embodiments, by adjusting the second supply voltage to/from the first value and the second value, the integrated circuit has a flexible design that can be configured to operate at two different voltage ranges, thereby reducing the power consumption of the integrated circuit compared with other approaches that have only a single operating voltage range that is inflexible and consume more power.

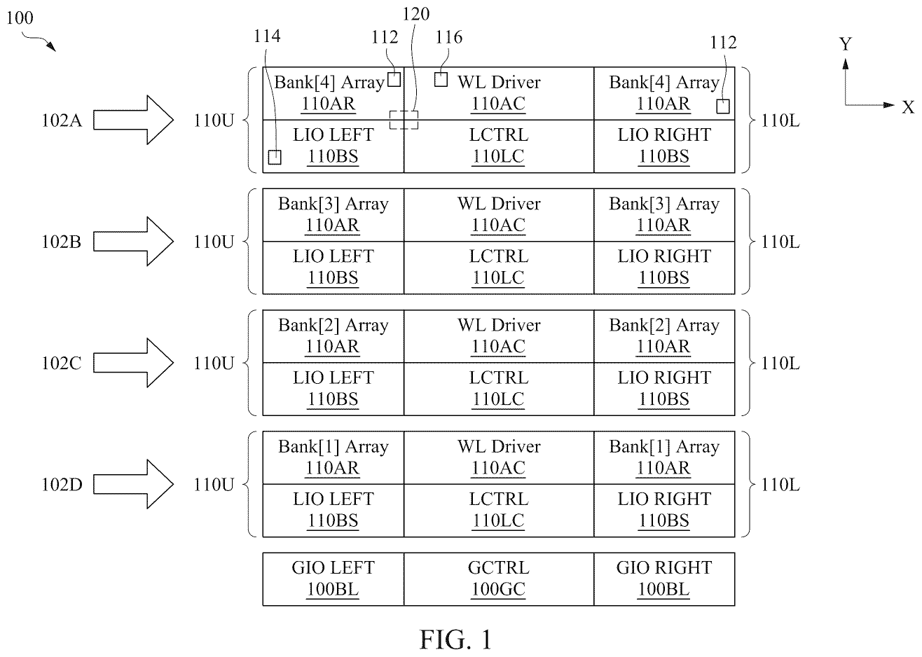

FIG. 1 is a block diagram of a memory circuit 100, in accordance with some embodiments.

FIG. 1 is simplified for the purpose of illustration. In some embodiments, memory circuit 100 includes various elements in addition to those depicted in FIG. 1 or is otherwise arranged to perform the operations discussed below.

Memory circuit 100 is an IC that includes memory partitions 102A-102D, a global control circuit 100GC and global input output (GIO) circuits 100BL.

Each memory partition 102A-102D includes memory banks 110U and 110L adjacent to a word line (WL) driver circuit 110AC and a local control circuit 110LC. Each memory bank 110U and 110L includes a memory cell array 110AR and a local input output (LIO) circuit 110BS.

A memory partition, e.g., a memory partition 102A-102D, is a portion of memory circuit 100 that includes a subset of memory devices (not shown in FIG. 1) and adjacent circuits configured to selectively access the subset of memory devices in program and read operations. In the embodiment depicted in FIG. 1, memory circuit 100 includes a total of four partitions. In some embodiments, memory circuit 100 includes a total number of partitions greater or fewer than four.

GIO circuit 100BL is a circuit configured to control access to one or more electrical paths, e.g., bit lines, to each memory device of the corresponding memory bank 110U or 110L of each memory partition 102A-102D, e.g., by generating one or more bit line signals. In some embodiments, GIO circuit 100BL includes a global bit line driver circuit. In some embodiments, GIO circuit 100BL is coupled to each memory bank 110U and 110L by a corresponding global bit line (not shown).

Global control circuit 100GC is a circuit configured to control some or all of program and read operations on each memory partition 102A-102D, e.g., by generating and/or outputting one or more control and/or enable signals.

In some embodiments, global control circuit 100GC includes one or more analog circuits configured to interface with memory partitions 102A-102D, cause data to be programmed in one or more memory devices, and/or use data received from one or more memory devices in one or more circuit operations. In some embodiments, global control circuit 100GC includes one or more global address decoder or pre-decoder circuits configured to output one or more address signals to the WL driver circuit 110AC of each memory partition 102A-102D.

Each WL driver circuit 110AC is configured to generate word line signals on corresponding word lines WL. In some embodiments, each WL driver circuit 110AC is configured to output word line signals on corresponding word lines WL to the adjacent memory banks 110U and 110L of the corresponding memory partition 102A-102D.

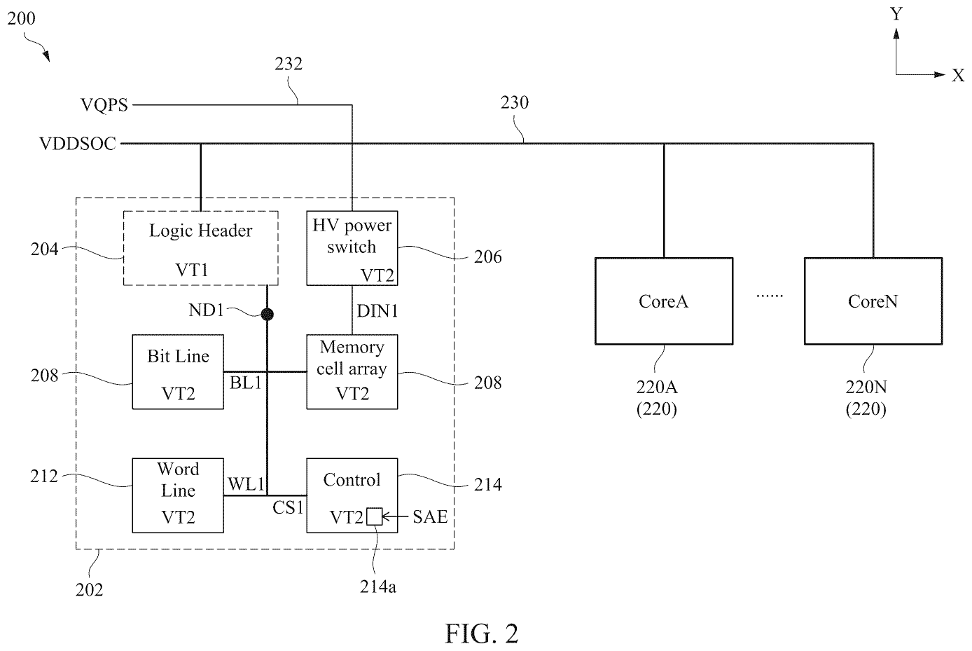

Each WL driver circuit 110AC includes one or more circuits 116. For ease of illustration, circuit 116 is not shown in memory bank 110U and 110L of memory partitions 102B, 102C and 102D. In some embodiments, each circuit 116 includes at least one word line driver circuit or at least at least one tracking word line driver circuit. In some embodiments, at least one word line driver circuit is configured to generate a word line signal WL1 (shown at least in FIG. 2). In some embodiments, at least one tracking word line driver circuit is configured to generate a tracking word line signal (not shown). In some embodiments, each circuit 116 in WL driver circuit 110AC is coupled to a corresponding row of memory devices 112 in memory cell array 110AR.

Each local control circuit 110LC is an electronic circuit configured to receive one or more address signals. Each local control circuit 110LC is configured to generate signals corresponding to adjacent subsets of memory devices identified by the one or more address signals. In some embodiments, the adjacent subsets of memory devices correspond to columns of memory devices. In some embodiments, each local control circuit 110LC is configured to generate each signal as a complementary pair of signals. In some embodiments, each local control circuit 110LC is configured to output the signals to corresponding word line driver circuits within the adjacent WL driver circuit 110AC of the corresponding memory partition 102A-102D. In some embodiments, the local control circuit 110LC includes a bank decoder circuit. Other types of control circuits for local control circuit 110LC are within the scope of the present disclosure.

Each LIO circuit 110BS is configured to selectively access one or more bit lines (shown in FIG. 2) coupled to adjacent subsets of memory devices of the corresponding memory cell array 110AR responsive to GIO circuit 100BL, e.g., based on one or more BL control signals. In some embodiments, the adjacent subsets of memory devices correspond to rows of memory devices. In some embodiments, the LIO circuit 110BS includes a bit line selection circuit.

Each LIO circuit 110BS includes one or more circuits 114. For ease of illustration, circuit 114 is not shown in memory bank 110U and 110L of memory partitions 102B, 102C and 102D. In some embodiments, each circuit 114 includes at least one bit line driver circuit. In some embodiments, at least one bit line driver circuit is configured to generate a bit line signal BL1 (shown at least in FIG. 2). In some embodiments, each circuit 116 is coupled to a corresponding column of memory devices 112 in memory cell array 110AR.

In some embodiments, each circuit 114 further includes at least a sense amplifier circuit and a write-in latch circuit. During a write operation, the write-in latch circuit is configured to write data into at least one memory cell 112 in a corresponding column of memory cells in the corresponding memory cell array 110AR, in accordance with some embodiments. During a read operation, the sense amplifier circuit is configured to read data from at least one memory cell 112 in a corresponding column of memory cells in the corresponding memory cell array 110AR, in accordance with some embodiments. In some embodiments, each circuit 114 in LIO circuit 110BS is coupled to a corresponding column of memory devices 112 in memory cell array 110AR.

In some embodiments, one or more of LIO circuit 110BS, local control circuit 110LC, WL driver circuit 110AC, GIO circuit 100BL or global control circuit 100GC includes a memory circuit 120.

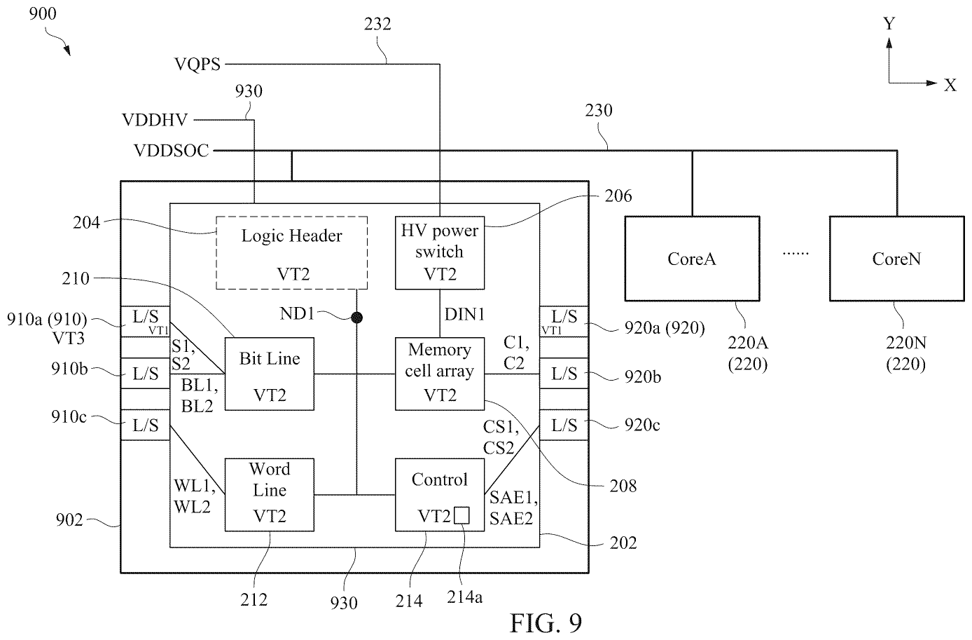

In some embodiments, memory circuit 120 is coupled to at least one of a power rail 232 (shown in FIGS. 2 & 9) configured to supply a supply voltage VQPS or a power rail 230 configured to supply a supply voltage VDDSOC. In some embodiments, memory circuit 120 is further coupled to a power rail 930 (shown in FIG. 9) configured to supply a supply voltage VDDHV.

In some embodiments, supply voltage VDDSOC is different from the supply voltage VQPS. In some embodiments, supply voltage VDDHV is different from the supply voltage VQPS and the supply voltage VDDSOC.

In some embodiments, memory circuit 120 is configured to supply the supply voltage VQPS or the supply voltage VDDSOC to at least one of circuit 112, 114 or 116. In some embodiments, memory circuit 120 is further configured to supply the supply voltage VDDHV to at least one of circuit 112, 114 or 116.

In some embodiments, memory circuit 120 is also referred to as a power gating circuit.

In some embodiments, memory circuit 120 includes at least one or more circuit 112, 114 or 116.

Each memory bank 110U and 110L includes the corresponding memory cell array 110AR including memory cells or memory devices 112 configured to be accessed in program and read operations by the adjacent LIO circuit 110BS and the adjacent WL driver circuit 110AC.

Each memory cell array 110AR includes an array of memory devices 112 having N rows and M columns, where M and N are positive integers. The rows of cells in memory cell array 102 are arranged in a first direction X. The columns of cells in memory cell array 102 are arranged in a second direction Y. The second direction Y is different from the first direction X. In some embodiments, the second direction Y is perpendicular to the first direction X. In some embodiments, each memory cell array 110AR is divided into an upper region and a lower region (not shown). In some embodiments, each column of memory devices 112 in memory cell array 110AR is coupled to a corresponding circuit 114 in LIO circuit 110BS.

Memory device 112 is shown in memory bank 110U and 110L of memory partition 102A. For ease of illustration, memory device 112 is not shown in memory bank 110U and 110L of memory partitions 102B, 102C and 102D.

Memory device 112 is an electrical, electromechanical, electromagnetic, or other device configured to store bit data represented by logical states. At least one logical state of memory device 112 is capable of being programmed in a write operation and detected in a read operation. In some embodiments, a logical state corresponds to a voltage level of an electrical charge stored in a given memory device 112. In some embodiments, a logical state corresponds to a physical property, e.g., a voltage, a current, a resistance or a magnetic orientation, of a component of a given memory device 112.

In some embodiments, memory device 112 includes one or more one-time programmable (OTP) memory devices. In some embodiments, memory device 112 includes one or more electronic fuse (eFuse) devices. In some embodiments, memory device 112 includes one or more anti-fuse devices. In some embodiments, memory device 112 is an OTP memory device including one or more OTP memory cells. Different types of memory cells in memory device 112 are within the contemplated scope of the present disclosure. In some embodiments, memory device 112 includes one or more flash memory devices, random-access memory (RAM) devices, resistive RAM devices, ferroelectric RAM devices, magneto-resistive RAM devices, erasable programmable read only memory (EPROM) devices, electrically erasable programmable read only memory (EEPROM) devices, or the like. In some embodiments, memory device 112 includes one or more single port (SP) static random access memory (SRAM) cells. In some embodiments, memory device 112 includes one or more dual port (DP) SRAM cells. In some embodiments, memory device 112 includes one or more multi-port SRAM cells. In some embodiments, memory device 112 includes one or more dynamic random access memory (DRAM) cells.

Other configurations of memory circuit 100 are within the scope of the present disclosure.

FIG. 2 is a circuit diagram of an integrated circuit 200, in accordance with some embodiments.

In some embodiments, integrated circuit 200 is usable in FIG. 1. Integrated circuit 200 is an embodiment of circuit 120 of FIG. 1, and similar detailed description is therefore omitted.

In some embodiments, integrated circuit 200 is an embodiment of at least a portion of one or more of memory partition 102A, 102B, 102C or 102D of FIG. 1, and similar detailed description is therefore omitted. In some embodiments, integrated circuit 200 is an embodiment of memory cell array 110AR of FIG. 1, LIO circuit 110BS of FIG. 1 and WL driver circuit 110AC, and similar detailed description is therefore omitted.

Integrated circuit 200 comprises a memory circuit 202 and a set of core devices 220.

Memory circuit 202 comprises a header circuit 204, a power switch 206, a memory cell array 208, a bit line driver circuit 210, a word line driver circuit 212, a control circuit 214, a power rail 230 and a power rail 232.

In some embodiments, memory cell array 208 is an embodiment of one or more memory cells MCB in at least one of memory cell array 110AR of FIG. 1 or memory device 112 of FIG. 1, and similar detailed description is therefore omitted.

In some embodiments, at least one of bit line driver circuit 210, control circuit 214 or power switch 206 is an embodiment of one or more circuits 114 in at least one of LIO circuit 110BS of FIG. 1, and similar detailed description is therefore omitted.

In some embodiments, word line driver circuit 212 is an embodiment of one or more circuits 116 in at least one of WL driver circuit 110AC of FIG. 1, and similar detailed description is therefore omitted.

Memory circuit 202 is coupled to the power rail 230, the power rail 232 and the set of core devices 220.

Memory circuit 202 is coupled to power rails 230 and 232.

Power rail 230 has a supply voltage VDDSOC.

Power rail 232 has a supply voltage VQPS. In some embodiments, the supply voltage VQPS is greater than the supply voltage VDDSOC. In some embodiments, the supply voltage VQPS ranges from about 1.5 volts to about 2.0 volts. In some embodiments, the supply voltage VDDSOC ranges from about 0.45 volts to about 1.0 volt. Other supply voltage values for the supply voltage VQPS or the supply voltage VDDSOC are within the scope of the present disclosure.

Memory circuit 202 is configured to receive supply voltage VDDSOC from power rail 230, and to receive supply voltage VQPS from power rail 232.

Header circuit 204 is coupled to the power rail 230. Header circuit 204 is configured to receive the supply voltage VDDSOC from the power rail 230. Header circuit 204 is configured to supply the supply voltage VDDSOC to at least node ND1.

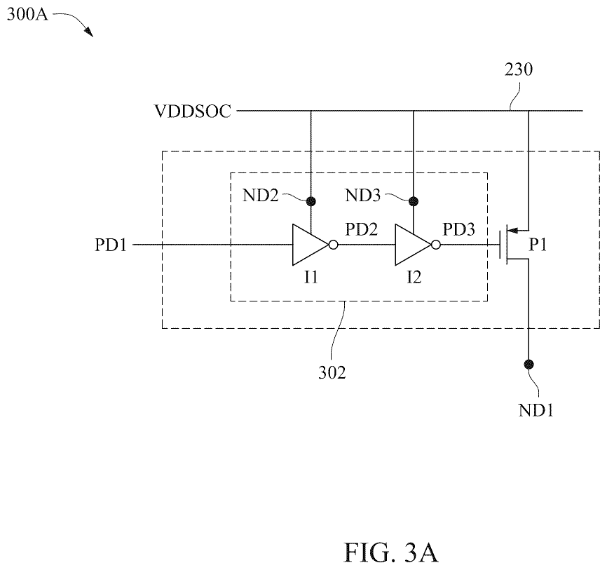

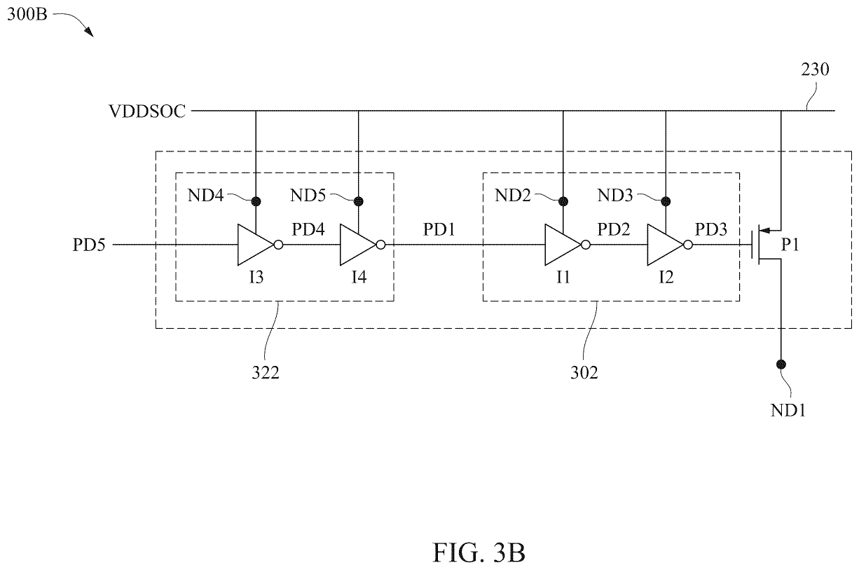

In some embodiments, header circuit 204 is configured to supply the supply voltage VDDSOC to at least one of memory cell array 208, bit line driver circuit 210, word line driver circuit 212 or control circuit 214 in response to a control signal PD1 (e.g., FIG. 3A) or a control signal PD5 (e.g., FIG. 3B). In some embodiments, header circuit 204 is also referred to as a power gating circuit.

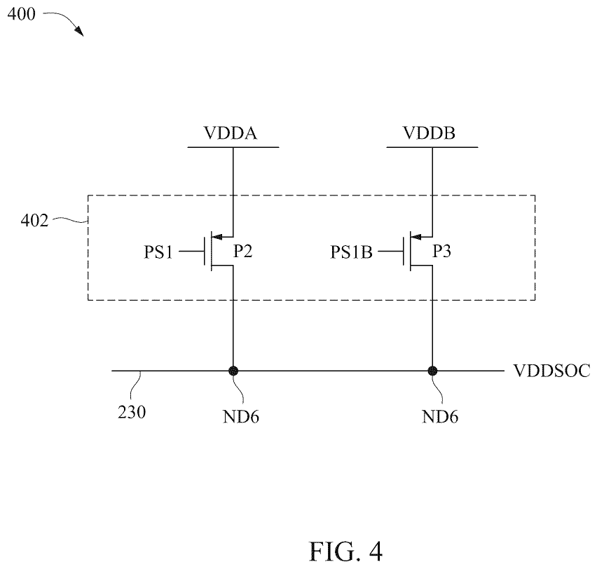

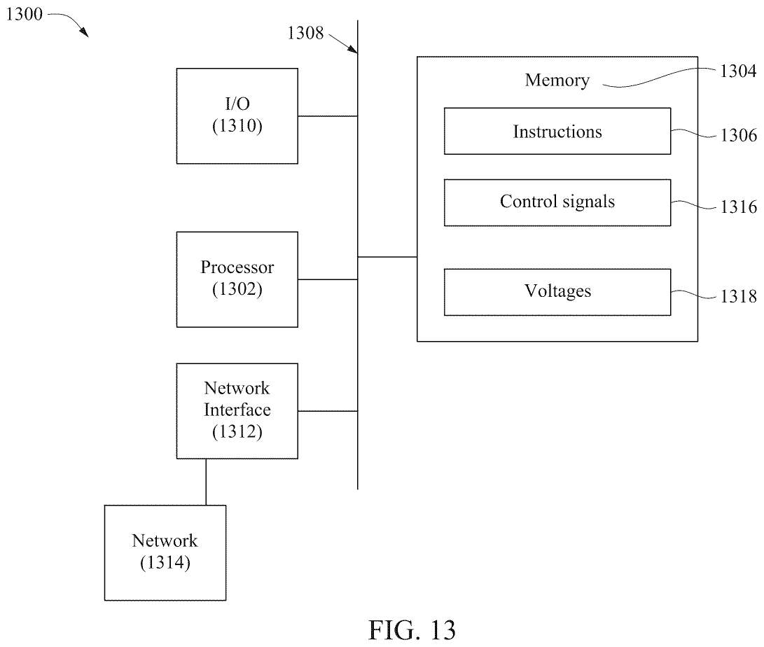

In some embodiments, the supply voltage VDDSOC is adjusted from a supply voltage VDDA to a supply voltage VDDB, and vice versa. In some embodiments, the supply voltage VDDSOC is set and adjusted by a circuit, such as controller 1300 of FIG. 13. In some embodiments, the supply voltage VDDSOC is set and adjusted by a circuit, such as circuit 400 of FIG. 4. In some embodiments, the supply voltage VDDA is less than the supply voltage VDDB. In some embodiments, the supply voltage VDDA ranges from about 0.4 volts to about 0.6 volts. In some embodiments, the supply voltage VDDB ranges from about 0.6 volts to about 1.0 volt. Other supply voltage values for the supply voltage VDDA or the supply voltage VDDB are within the scope of the present disclosure.

In some embodiments, when the supply voltage VDDSOC is set to be equal to the supply voltage VDDA, then integrated circuit 200 is configured to be in a sleep mode or a power down mode, thereby reducing the power consumption of integrated circuit 200 compared with other approaches.

In some embodiments, when the supply voltage VDDSOC is set to be equal to the supply voltage VDDA, then header circuit 204 is disabled and is configured to be in a sleep mode or a power down mode, and one or more of the memory cell array 208, the bit line driver circuit 210, the word line driver circuit 212, the sense amplifier 214a of control circuit 214 or the power switch 206 is disabled and/or configured to be in the sleep mode or the power down mode, thereby reducing the power consumption of integrated circuit 200 compared with other approaches

In some embodiments, when the supply voltage VDDSOC is set to be equal to the supply voltage VDDB, then integrated circuit 200 is configured to be in a read mode, program mode or a standby mode. In some embodiments, when the supply voltage VDDSOC is set to be equal to the supply voltage VDDB, then header circuit 204 is enabled, and one or more of the memory cell array 208, the bit line driver circuit 210, the word line driver circuit 212, the sense amplifier 214a of control circuit 214 or the power switch 206 is enabled and/or configured to be in the read mode, the program mode or the standby mode.

In some embodiments, by adjusting the supply voltage VDDSOC to/from the supply voltage VDDA to the supply voltage VDDB, memory circuit 202 has a flexible design that can be configured to operate at two different voltage ranges (e.g., VDDA & VDDB), thereby reducing the power consumption of integrated circuit 200 compared with other approaches that only have a single operating voltage range that is inflexible and consume more power.

In some embodiments, by adjusting the supply voltage VDDSOC to/from the supply voltage VDDA to the supply voltage VDDB, memory circuit 202 has a flexible design that can be configured to operate at two different voltage ranges (e.g., VDDA & VDDB), thereby reducing the leakage current from power rail 230 to at least node ND1 in the sleep mode or the power down mode, thus reducing the power consumption of integrated circuit 200 compared with other approaches that only have a single operating voltage range that is inflexible and consume more power.

Header circuit 204 is further coupled to one or more of memory cell array 208, bit line driver circuit 210, word line driver circuit 212 or control circuit 214 by a node ND1. In some embodiments, header circuit 204 is configured to supply the supply voltage VDDSOC to at least one of memory cell array 208, bit line driver circuit 210, word line driver circuit 212 or control circuit 214 by node ND1.

In some embodiments, at least one of memory cell array 208, bit line driver circuit 210, word line driver circuit 212 or control circuit 214 is configured to operate on the supply voltage VDDSOC received from the header circuit 204.

Other configurations, elements or quantities of elements in header circuit 204 are within the scope of the present disclosure.

Memory cell array 208 is coupled to the header circuit 204 by the node ND1. Memory cell array 208 is configured to receive the supply voltage VDDSOC from the header circuit 204 by the node ND1. Memory cell array 208 is configured to store a set of data DIN1.

Other configurations, elements or quantities of elements in memory cell array 208 are within the scope of the present disclosure.

The bit line driver circuit 210 is coupled to the header circuit 204 by the node ND1. The bit line driver circuit 210 is configured to receive the supply voltage VDDSOC. The bit line driver circuit 210 is configured to generate a bit line signal BL. In some embodiments, the bit line driver circuit 210 is configured to receive the bit line signal BL.

Other configurations, elements or quantities of elements in bit line driver circuit 210 are within the scope of the present disclosure.

The word line driver circuit 212 is coupled to the header circuit 204 by the node ND1. The word line driver circuit 212 is configured to receive the supply voltage VDDSOC. The word line driver circuit 212 is configured to generate the word line signal WL. In some embodiments, the word line driver circuit 212 is configured to receive the word line signal WL.

Other configurations, elements or quantities of elements in word line driver circuit 212 are within the scope of the present disclosure.

The control circuit 214 is coupled to the header circuit 204 by the node ND1. The control circuit 214 is configured to receive the supply voltage VDDSOC. In some embodiments, the control circuit 214 is configured to perform one or more control operations of memory cell array 208. In some embodiments, the control circuit 214 is configured to perform one or more read operations of memory cell array 208 in response to one or more corresponding sense amplifier enable signals (SAE).

In some embodiments, the control circuit 214 includes at least one sense amplifier circuit 214a.

In some embodiments, the sense amplifier circuit 214a is coupled to the header circuit 204 by the node ND1. In some embodiments, the sense amplifier circuit 214a is configured to receive the supply voltage VDDSOC. In some embodiments the sense amplifier circuit 214a is configured to perform one or more read operations of memory cell array 208 in response to one or more corresponding sense amplifier enable signals (SAE).

In some embodiments, the control circuit 214 includes other types of circuits. In some embodiments, the control circuit 214 includes at least one level shifter circuit similar to the set of level shifter circuits 910 or 920 of FIG. 9, and similar detailed description is therefore omitted. In some embodiments, the control circuit 214 includes at least one charge pump circuit, low-dropout (LDO) circuit, a bandgap circuit, a detector circuit or a voltage generator circuit.

Other configurations, elements or quantities of elements in control circuit 214 or sense amplifier circuit 214a are within the scope of the present disclosure.

The power switch 206 is coupled to the power rail 232. The power switch 206 is configured to receive the supply voltage VQPS. In some embodiments, the power switch 206 is configured to supply the supply voltage VQPS to the memory cell array 208 in response to a write driver circuit (such as circuit 114 in FIG. 1) performing a write operation of the memory cell array 208.

In some embodiments, the power switch 206 includes one or more transistors, similar to transistor P1 of FIGS. 3A-3B, and similar detailed description is therefore omitted. In some embodiments, the power switch 206 includes at least one level shifter circuit similar to the set of level shifter circuits 910 or 920 of FIG. 9, and similar detailed description is therefore omitted.

Other configurations, elements or quantities of elements in power circuit 206 are within the scope of the present disclosure.

Other configurations, elements or quantities of elements in memory circuit 202 are within the scope of the present disclosure.

The set of core devices 220 is coupled to the power rail 230. In some embodiments, the set of core devices 220 is coupled to the memory circuit 202 and the power rail 230. The set of core devices 220 is configured to receive the supply voltage VDDSOC from the power rail 230.

In some embodiments, at least one circuit element in the set of core devices 220 or at least one core device in the set of core devices 220 is configured to operate on the supply voltage VDDSOC. In some embodiments, at least one circuit element in the set of core devices 220 or at least one core device in the set of core devices 220 is configured to operate on the supply voltage VDDA.

In some embodiments, the set of core devices 220 includes at least one or more of core devices 220A, . . . 220N, where N is an integer corresponding to a number of core devices in the set of core devices 220.

In some embodiments, at least one core device of the set of core devices 220 includes one or more of a central processing unit (CPU) core, a graphics processing unit (GPU) core or a memory controller core.

Other configurations, elements or quantities of elements in the set of core devices 220 are within the scope of the present disclosure.

In some embodiments, at least one of the transistors in the header circuit 204 has a threshold voltage VT1. In some embodiments, at least one of the transistors in the memory cell array 208, the bit line driver circuit 210, the word line driver circuit 212, the sense amplifier 214a of control circuit 214 or the power switch 206 has a threshold voltage VT2. In some embodiments, the threshold voltage VT2 is greater than the threshold voltage VT1.

In some embodiments, a threshold voltage of a transistor device is related to one or more of a work function difference between a channel of a transistor and the gate electrode of the transistor, an amount of p-type or n-type dopants in the transistor device or a thickness of a gate oxide of the corresponding gate in the transistor device, or the like.

For example, in some embodiments, by increasing the work function difference between the channel of an NMOS transistor and the gate electrode of the NMOS transistor causes the threshold voltage of the NMOS transistor to be increased, and vice versa. For example, in some embodiments, by increasing the work function difference between the channel of an PMOS transistor and the gate electrode of the PMOS transistor causes the threshold voltage of the PMOS transistor to be decreased, and vice versa.

For example, in some embodiments, by decreasing the thickness of the gate oxide of the transistor device causes the threshold voltage of the transistor device to be decreased.

For example, in some embodiments, by increasing the P-type dopant concentration of the channel in an NMOS transistor causes the threshold voltage to be increased. In some embodiments, by increasing the N-type dopant concentration of the channel in an NMOS transistor causes the threshold voltage to be decreased.

In some embodiments, by configuring the memory circuit 202 to have different threshold voltages reduces the leakage current in a path including node ND1, thereby reducing the power consumption of integrated circuit 200 compared with other approaches that have higher leakage current and greater power consumption.

In some embodiments, by configuring the memory circuit 202 with a header circuit 204 reduces the leakage current in the path including node ND1 when one or more of memory cell array 208, bit line driver circuit 210, word line driver circuit 212, control circuit 214 or power switch 206 is disabled or is in sleep mode (e.g., power down mode), thereby reducing the power consumption of integrated circuit 200 compared with other approaches that have higher leakage current and greater power consumption.

Other configurations, elements or quantities of elements in integrated circuit 200 are within the scope of the present disclosure.

FIG. 3A is a block diagram of a circuit 300A usable in at least FIG. 2 or FIG. 9, in accordance with some embodiments.

In some embodiments, circuit 300A is an embodiment of header circuit 204 of FIG. 2 or header circuit 204 of FIG. 9, and similar detailed description is therefore omitted.

Circuit 300A comprises power rail 230, a set of inverters 302 and a transistor P1.

Power rail 230 is coupled to the set of inverters 302 and the transistor P1.

The set of inverters 302 includes at least one of inverter I1 or I2.

The inverter I1 is coupled to the power rail 230 and inverter I2.

The inverter I1 is configured to receive a control signal PD1. The inverter I1 is configured to generate a control signal PD2 in response to the control signal PD1. In some embodiments, the control signal PD1 is inverted from the control signal PD2.

In some embodiments, the inverter I1 comprises an input terminal, an output terminal and a voltage supply node ND2. In some embodiments, the voltage supply node ND2 is coupled to the power rail 230. In some embodiments, the voltage supply node ND2 is configured to receive the supply voltage VDDSOC from the power rail 230. In some embodiments, the inverter I1 is configured to operate on the supply voltage VDDSOC. In some embodiments, the input terminal of the inverter I1 is configured to receive the control signal PD1. In some embodiments, the output terminal of the inverter I1 is configured to output the second control signal PD2. In some embodiments, the output terminal of the inverter I1 is coupled to an input terminal of the inverter I2.

In some embodiments, the control signal PD1 is generated by a circuit, such as controller 1300 of FIG. 13. In some embodiments, the input terminal of inverter I1 is coupled to controller 1300 of FIG. 13.

The inverter I2 is coupled to the first power rail (VDDSOC), the inverter I1 and transistor P1.

The inverter I2 is configured to receive the control signal PD2. The inverter I2 is configured to generate a control signal PD3 in response to the control signal PD2. In some embodiments, the control signal PD3 is inverted from the control signal PD2.

In some embodiments, the inverter I2 comprises an input terminal, an output terminal and a voltage supply node ND3. In some embodiments, the voltage supply node ND3 is coupled to the power rail 230. In some embodiments, the voltage supply node ND3 is configured to receive supply voltage VDDSOC from the power rail 230. In some embodiments, the inverter I2 is configured to operate on the supply voltage VDDSOC. In some embodiments, the input terminal of the inverter I2 is configured to receive the control signal PD2. In some embodiments, the output terminal of the inverter I2 is configured to output the control signal PD3 to a gate terminal of transistor P1.

Transistor P1 is coupled to the power rail 230, the output terminal of the inverter I2 and the node ND1. In some embodiments, transistor P1 is a PMOS transistor. Other transistor types for transistor P1 are within the scope of the present disclosure. In some embodiments, transistor P1 is an NMOS transistor.

Transistor P1 includes a gate terminal configured to receive the control signal PD3. The gate terminal of transistor P1 is coupled to the output terminal of the inverter I2.

Transistor P1 further includes a source terminal coupled to the power rail 230. In some embodiments, the source terminal of transistor P1 is configured to receive the supply voltage VDDSOC. Transistor P1 further includes a drain terminal coupled to the node ND1.

In some embodiments, when transistor P1 is enabled or turned on, transistor P1 is configured to supply the supply voltage VDDSOC to node ND1. In some embodiments, when transistor P1 is disabled or turned off, transistor P1 is not configured to supply the supply voltage VDDSOC to node ND1.

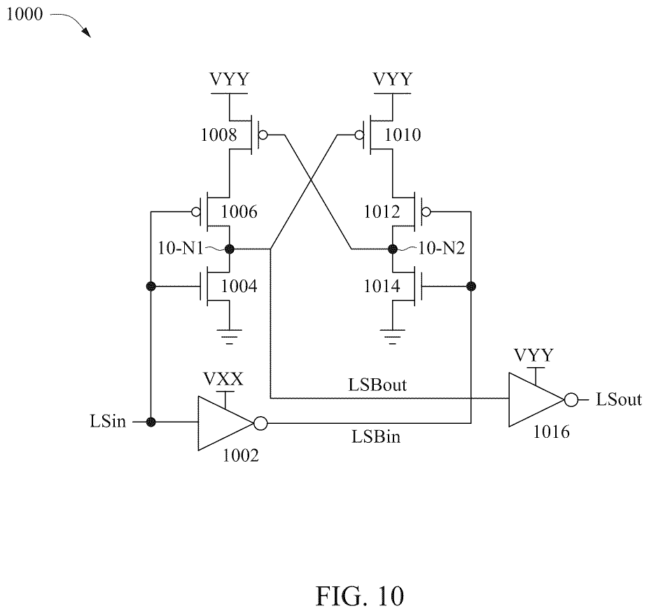

Selecting different numbers of inverters in FIGS. 3A-3B and 10 are within the scope of various embodiments. Selecting different numbers of transistors or types of transistors in FIGS. 3A-3B, 4, 5A-5B and 10 are within the scope of various embodiments.

Other configurations, elements or quantities of inverters for the set of inverters 302 in circuit 300A are within the scope of the present disclosure.

Other configurations, elements or quantities of transistors for transistor P1 in circuit 300A are within the scope of the present disclosure.

In some embodiments, by adjusting the supply voltage VDDSOC to/from the supply voltage VDDA to the supply voltage VDDB, circuits 300A-300B have a flexible design that can be configured to operate at two different voltage ranges (e.g., VDDA & VDDB), thereby reducing the leakage current that flows through transistor P1 from power rail 230 to at least node ND1, during the sleep mode or the power down mode, thus reducing the power consumption of circuits 300A-300B compared with other approaches that only have a single operating voltage range that is inflexible and consume more power.

Other configurations, elements or quantities of elements in circuit 300A are within the scope of the present disclosure.

FIG. 3B is a block diagram of a circuit 300B usable in at least FIG. 2 or FIG. 9, in accordance with some embodiments.

In some embodiments, circuit 300B is an embodiment of header circuit 204 of FIG. 2 or header circuit 204 of FIG. 9, and similar detailed description is therefore omitted.

Circuit 300B is a variation of circuit 300A of FIG. 3A, and similar detailed description is therefore omitted. For example, circuit 300B illustrates a non-limiting example where circuit 300B further includes a set of inverters 322, and similar detailed description is therefore omitted.

In comparison with circuit 300A of FIG. 3A, circuit 300B further includes the set of inverters 322, and similar detailed description is therefore omitted.

Circuit 300B comprises the power rail 230, the set of inverters 302 a set of inverters 402 and the transistor P1.

Power rail 230 is coupled to the set of inverters 302 and 322 and the transistor P1.

The set of inverters 322 includes at least one of inverter I3 or I4.

The inverter I3 is coupled to the power rail 230 and inverter I4.

The inverter I3 is configured to receive a control signal PD5. The inverter I3 is configured to generate a control signal PD4 in response to the control signal PD5. In some embodiments, the control signal PD5 is inverted from the control signal PD4.

In some embodiments, the inverter I3 comprises an input terminal, an output terminal and a voltage supply node ND4. In some embodiments, the voltage supply node ND4 is coupled to the power rail 230. In some embodiments, the voltage supply node ND4 is configured to receive the supply voltage VDDSOC from the power rail 230. In some embodiments, the inverter I3 is configured to operate on the supply voltage VDDSOC. In some embodiments, the input terminal of the inverter I3 is configured to receive the control signal PD5. In some embodiments, the output terminal of the inverter I3 is configured to output the second control signal PD4. In some embodiments, the output terminal of the inverter I3 is coupled to an input terminal of the inverter I4.

In some embodiments, the control signal PD5 is generated by a circuit, such as controller 1300 of FIG. 13. In some embodiments, the input terminal of inverter I3 is coupled to controller 1300 of FIG. 13.

The inverter I4 is coupled to the first power rail (VDDSOC), the inverter I3 and the inverter I1.

The inverter I4 is configured to receive the control signal PD4. The inverter I4 is configured to generate a control signal PD1 in response to the control signal PD4. In some embodiments, the control signal PD1 is inverted from the control signal PD4.

In some embodiments, the inverter I4 comprises an input terminal, an output terminal and a voltage supply node ND5. In some embodiments, the voltage supply node ND5 is coupled to the power rail 230. In some embodiments, the voltage supply node ND5 is configured to receive supply voltage VDDSOC from the power rail 230. In some embodiments, the inverter I4 is configured to operate on the supply voltage VDDSOC. In some embodiments, the input terminal of the inverter I4 is configured to receive the control signal PD4. In some embodiments, the output terminal of the inverter I4 is configured to output the control signal PD1 to the input terminal of inverter I1.

In comparison with circuit 300A of FIG. 3A, the input terminal of inverter I1 is coupled to the output terminal of the inverter I4, and similar detailed description is therefore omitted. In comparison with circuit 300A of FIG. 3A, the input terminal of inverter I1 is configured to receive the control signal PD1 from the output terminal of the inverter I4, and similar detailed description is therefore omitted.

Other configurations, elements or quantities of inverters for the set of inverters 302 or 322 in circuit 300B are within the scope of the present disclosure.

Other configurations, elements or quantities of transistors for transistor P1 in circuit 300B are within the scope of the present disclosure.

In some embodiments, circuit 300B achieves one or more of the benefits described herein.

Other configurations, elements or quantities of elements in circuit 300B are within the scope of the present disclosure.

FIG. 4 is a block diagram of a circuit 400 usable in at least FIG. 2 or FIG. 9, in accordance with some embodiments.

In some embodiments, circuit 400 is usable to supply the supply voltage to the power rail 230 of FIGS. 2, 3A, 3B, 5A, 5B, 6, 9, or 10, and similar detailed description is therefore omitted.

Circuit 400 comprises a circuit 402 and the power rail 230.

Circuit 402 is coupled to the power rail 230. In some embodiments, circuit 402 is configured to supply the supply voltage VDDA or VDDB to the power rail 230 as the supply voltage VDDSOC. In some embodiments, circuit 402 is configured to set and/or adjust the supply voltage VDDSOC as being equal to the supply voltage VDDA or the supply voltage VDDB.

Circuit 402 includes a transistor P2 and a transistor P3.

Transistor P2 is coupled to the power rail 230. In some embodiments, transistor P2 is a PMOS transistor. Other transistor types for transistor P2 are within the scope of the present disclosure. In some embodiments, transistor P2 is an NMOS transistor.

Transistor P2 includes a gate terminal configured to receive a control signal PS1. In some embodiments, the gate terminal of transistor P2 is coupled to a source of control signal PS1.

In some embodiments, the control signal PS1 is generated by a circuit, such as controller 1300 of FIG. 13. In some embodiments, the gate terminal of transistor P2 is coupled to controller 1300 of FIG. 13.

Transistor P2 further includes a source terminal coupled to a voltage supply VDDA'. In some embodiments, the source terminal of transistor P2 is configured to receive the supply voltage VDDA. Transistor P2 further includes a drain terminal coupled to the power rail 230.

Transistor P3 is coupled to the power rail 230. In some embodiments, transistor P3 is a PMOS transistor. Other transistor types for transistor P3 are within the scope of the present disclosure. In some embodiments, transistor P3 is an NMOS transistor.

Transistor P3 includes a gate terminal configured to receive a control signal PS1B. In some embodiments, the gate terminal of transistor P3 is coupled to a source of control signal PS1B.

In some embodiments, the control signal PS1B is inverted from the control signal PS1, and vice versa. In some embodiments, the control signal PS1B is generated by a circuit, such as controller 1300 of FIG. 13. In some embodiments, the gate terminal of transistor P3 is coupled to controller 1300 of FIG. 13.

Transistor P3 further includes a source terminal coupled to a voltage supply VDDB'. In some embodiments, the source terminal of transistor P3 is configured to receive the supply voltage VDDB. Transistor P3 further includes a drain terminal coupled to the power rail 230.

In some embodiments, when transistor P2 is enabled or turned on, then transistor P3 is disabled or turned off, and vice versa. In some embodiments, when transistor P3 is enabled or turned on, then transistor P2 is disabled or turned off, and vice versa.

In some embodiments, when transistor P2 is enabled or turned on, transistor P2 is configured to supply the supply voltage VDDA to the power rail 230. In some embodiments, when transistor P2 is enabled or turned on, transistor P2 is configured to set and/or adjust the supply voltage VDDSOC to be equal to the supply voltage VDDA.

In some embodiments, when transistor P3 is enabled or turned on, transistor P3 is configured to supply the supply voltage VDDB to the power rail 230. In some embodiments, when transistor P3 is enabled or turned on, transistor P3 is configured to set and/or adjust the supply voltage VDDSOC to be equal to the supply voltage VDDB.

In some embodiments, when transistor P2 is disabled or turned off, transistor P2 is not configured to supply the supply voltage VDDA to the power rail 230. In some embodiments, when transistor P2 is disabled or turned off, transistor P2 is not configured to set and/or adjust the supply voltage VDDSOC to be equal to the supply voltage VDDA.

In some embodiments, when transistor P3 is disabled or turned off, transistor P3 is not configured to supply the supply voltage VDDB to the power rail 230. In some embodiments, when transistor P3 is disabled or turned off, transistor P3 is not configured to set and/or adjust the supply voltage VDDSOC to be equal to the supply voltage VDDB.

Selecting different numbers of transistors or types of transistors in FIG. 4 are within the scope of various embodiments.

Other configurations, elements or quantities of transistors for transistor P2 are within the scope of the present disclosure. Other configurations, elements or quantities of transistors for transistor P3 are within the scope of the present disclosure.

In some embodiments, circuit 400 achieves one or more of the benefits described herein.

Other configurations, elements or quantities of elements in circuit 400 are within the scope of the present disclosure.

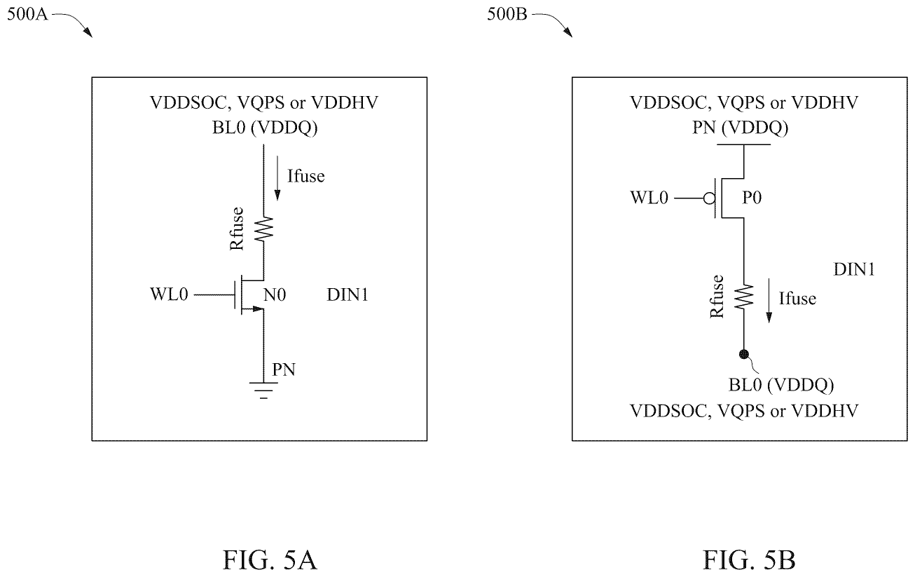

FIGS. 5A-5B are corresponding circuit diagrams of corresponding eFuse circuits 500A-500B, in accordance with some embodiments.

In some embodiments, at least one of circuit 500A or 500B is an embodiment of memory device 112 of FIG. 1, and similar detailed description is therefore omitted. In some embodiments, at least one of circuit 500A or 500B is an embodiment of one or more memory cells MCB in at least one of memory cell array 110AR of FIG. 1, and similar detailed description is therefore omitted.

In some embodiments, at least one of circuit 500A or 500B is configured to store a data signal DIN1.

Circuit 500A includes an eFuse Rfuse coupled between a program node PN and a bit line BL0.

Circuit 500A further includes an n-type metal-oxide semiconductor (NMOS) transistor N0 coupled between the eFuse Rfuse and the program node PN.

A gate of NMOS transistor N0 is coupled with a word line WL0. The gate of NMOS transistor N0 is configured to receive a word line signal from the word line WL0.

Two or more circuit elements are considered to be coupled based on a direct electrical connection, a resistive or reactive electrical connection, or an electrical connection that includes one or more additional circuit elements and is thereby capable of being controlled, e.g., made resistive or open by a transistor or other switching device.

A source of NMOS transistor N0 is coupled with the program node PN. In some embodiments, the program node PN is coupled to a reference voltage supply VSS. A voltage of the reference voltage supply VSS is a reference voltage VSS′.

A drain of NMOS transistor N0 is coupled with a first end of the eFuse Rfuse. A second end of the eFuse Rfuse is coupled with the bit line BL0. In some embodiments, the bit line BL0 is coupled to a voltage supply VDDQ. The voltage of the voltage supply VDDQ is a voltage VDDQ′. In some embodiments, the bit line BL0 is configured to supply a current Ifuse.

In some embodiments, the voltage supply VDDQ includes one or more of power rail 230, 232 or 930. In some embodiments, the supply voltage VDDQ′ includes one or more of supply voltage VDDSOC, supply voltage VQPS or supply voltage VDDHV (FIG. 9).

Circuit 500B is a variation of circuit 500A. In comparison with circuit 500A, a p-type metal-oxide semiconductor (PMOS) transistor P0 replaces the NMOS transistor N0, and similar detailed description is therefore omitted.

Circuit 500B includes the PMOS transistor P0 coupled between the eFuse Rfuse and the program node PN.

A gate of PMOS transistor P0 is coupled with the word line WL0. The gate of PMOS transistor P0 is configured to receive the word line signal from the word line WL0.

A source of PMOS transistor P0 is coupled with the program node PN. In some embodiments, the program node PN is coupled to the voltage supply VDDQ.

A drain of PMOS transistor P0 is coupled with the first end of the eFuse Rfuse. A second end of the eFuse Rfuse is coupled with the bit line BL0. In some embodiments, the bit line BL0 is coupled to the reference voltage supply VSS. In some embodiments, the bit line BL0 is configured to receive current Ifuse.

In some embodiments, circuit 500A-500B is some or all of a bit cell of a plurality of bit cells in which each bit cell is coupled with bit line BL0. In some embodiments, bit line BL0 is one bit line of a plurality of bit lines. In some embodiments, a circuit 500A-500B is some or all of a bit cell of a plurality of bit cells of a memory circuit (not shown).

In some embodiments, the word line WL0 is a word line of a memory circuit, and word line signals are configured to select a bit cell including a circuit 500A-500B in a programming or a read operation. In some embodiments, a memory circuit includes one or more sense amplifiers (not shown) configured to determine a programmed state of a circuit 500A-500B in a read operation.

EFuse Rfuse is a circuit device including a conductive element capable of being sustainably altered, and thereby programmed, by a current Ifuse having a magnitude that exceeds a predetermined current level. In some embodiments, in a non-programmed state, eFuse Rfuse has a small resistance relative to a resistance in a programmed state.

Each of NMOS transistor N0 and PMOS transistor P0 is a program device in an IC device that is capable of switching between conductive and resistive states responsive to an input signal, e.g., word line signal, received at a word line WL0. In a conductive state, the program device has a low resistance current path between two current path terminals (not labeled), and, in a resistive state, the program device has a high resistance current path between the two current path terminals.

In the conductive state, the program device is capable of having the low resistance current path only for current values up to a predetermined current saturation level, and has a significantly higher relative resistance path for current values above the saturation level. In operation, the program device thereby acts to limit the value of a current flowing between the two current path terminals in response to an increasing voltage difference across the two current path terminals.

While FIG. 5A shows the program device as NMOS transistor N0, and FIG. 5B shows the program device as PMOS transistor P0, in various embodiments, the program device includes a transmission gate, a MOS transistor, a field effect transistor (FET), a FinFET, a bipolar transistor, or other suitable IC device capable of switching between conductive and resistive states responsive to an input signal.

In the embodiment depicted in FIG. 5A, NMOS transistor N0 is configured to be in the conductive state responsive to the word line signal having a high logic level, and to be in the resistive state responsive to the word line signal having a low logic level.

In the embodiment depicted in FIG. 5B, PMOS transistor P0 is configured to be in the conductive state responsive to the word line signal having the low logic level, and to be in the resistive state responsive to the word line signal having the high logic level.

Other configurations, other number of fuse elements or other number of transistors in circuit 500A or 500B are within the scope of the present disclosure. For example, at least circuit 500A or 500B includes more than 1 fuse element (e.g., eFuse Rfuse). For example, at least circuit 500A or 500B includes more than 1 programming device (e.g., NMOS transistor N0 or PMOS transistor P0).

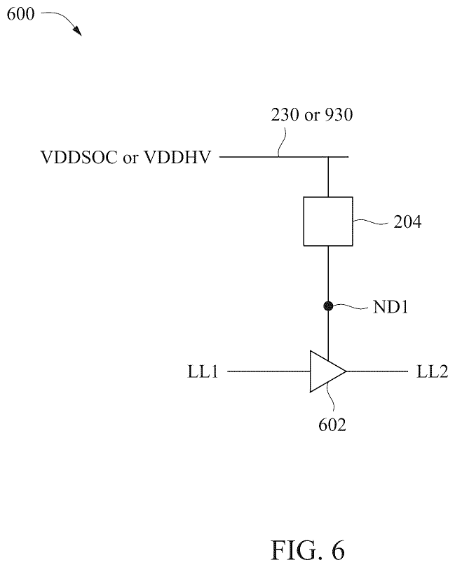

FIG. 6 is a block diagram of a circuit 600 usable in at least FIG. 2 or FIG. 9, in accordance with some embodiments.

In some embodiments, circuit 600 is usable as the power rail 230, the header circuit 204 and one of the bit line driver circuit 210 or the word line driver circuit 212 of FIG. 1, and similar detailed description is therefore omitted.

Circuit 600 comprises a buffer circuit 602, header circuit 204 and the power rail 230.

The buffer circuit 602 is coupled to the header circuit 204 by the node ND1. The buffer circuit 602 is configured to receive the supply voltage VDDSOC or VDDHV from the corresponding power rail 230 or 930 by the header circuit 204. A voltage supply node of the buffer circuit 602 is coupled to the header circuit 204 by node ND1. In some embodiments, the buffer circuit 602 is configured to operate on the supply voltage VDDSOC or the supply voltage VDDHV.

In some embodiments, the buffer circuit 602 is configured to receive a signal LL1. The buffer circuit 602 is configured to generate a signal LL2 in response to a signal LL1. In some embodiments, signal LL2 is a delayed version of LL1. In some embodiments, buffer circuit 602 is an inverter circuit, and signal LL2 is an inverted version of LL1.

In some embodiments, buffer circuit 602 is the bit line driver circuit 210 of FIGS. 2 and 9, and buffer circuit 602 is configured to generate a bit line signal BL (e.g., signal LL2).

In some embodiments, buffer circuit 602 is the word line driver circuit 212 of FIGS. 2 and 9, and buffer circuit 602 is configured to generate a word line signal WL (e.g., signal LL2).

In some embodiments, buffer circuit 602 is the bit line driver circuit 210 of FIG. 2 or 9, and the signal LL2 is the bit line signal BL of FIG. 2 or at least one of bit line signal BL1 or BL2 in FIG. 9, and similar detailed description is therefore omitted.

In some embodiments, buffer circuit 602 is the word line driver circuit 212 of FIG. 2 or 9, and the signal LL2 is the word line signal WL of FIG. 2 or at least one of word line signal WL1 or WL2 in FIG. 9, and similar detailed description is therefore omitted.

Selecting different numbers of circuit elements or types of circuit elements in FIG. 6 are within the scope of various embodiments.

In some embodiments, circuit 600 achieves one or more of the benefits described herein.

Other configurations, elements or quantities of elements in circuit 600 are within the scope of the present disclosure.

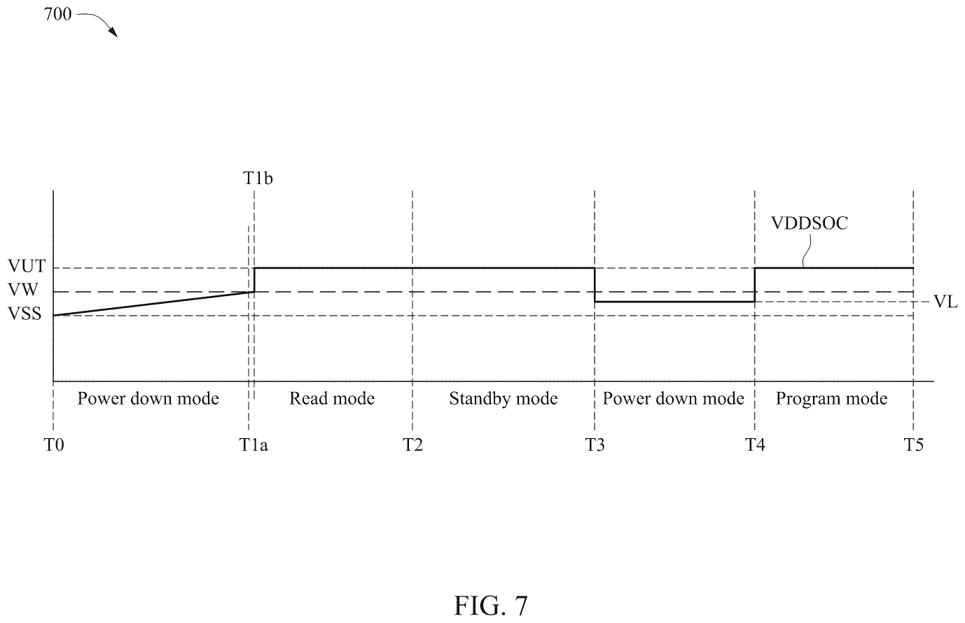

FIG. 7 is a timing diagram 700 of waveforms of an integrated circuit, in accordance with some embodiments.

In some embodiments, FIG. 7 is a timing diagram 700 of waveforms of integrated circuit 200 in FIG. 2.

In some embodiments, one or more power down operations, standby operations, read operations, write/program operations are applied to a memory cell in memory cell array 208 of FIG. 2 or at least one memory cell in a single column of memory cell array 110AR of FIG. 1, and timing diagram 700 corresponds to waveforms during the one or more power down operations, standby operations, read operations or write/program operations of memory cell array 208 of FIG. 2 or at least one memory cell in a single column of memory cell array 110AR of FIG. 1.

In some embodiments, one or more power down operations, standby operations, read operations or write/program operations of the memory banks in at least memory circuit 100 of FIG. 1 are applied to at least one of memory partition 102A, 102B, 102C or 102D, and timing diagram 700 corresponds to waveforms during the one or more power down operations, standby operations, read operations or write/program operations of at least one of memory partition 102A, 102B, 102C or 102D.

Timing diagram 700 includes waveforms of the supply voltage VDDSOC, a voltage VUT or a voltage VW.

In some embodiments, the supply voltage VDDSOC ranges from about the reference voltage supply VSS to about voltage VUT.

In some embodiments, the voltage VUT is greater than the voltage VW. In some embodiments, the voltage VUT is a maximum voltage of one or more circuit elements in the integrated circuit 200, and similar detailed description is therefore omitted. In some embodiments, the voltage VW is a working voltage of one or more circuit elements in the integrated circuit 200, and similar detailed description is therefore omitted. In some embodiments, the voltage VW is a threshold voltage of one or more circuit elements in the integrated circuit 200, and similar detailed description is therefore omitted.

In some embodiments, the voltage VUT ranges from about 0.6 volts to about 2.0 volts. In some embodiments, the voltage VW ranges from about 0.4 volts to about 1.8 volts.

Prior to time T0, the supply voltage VDDSOC is substantially equal to the reference supply voltage VSS (e.g., 0 volts).

In some embodiments, a first element is substantially equal to a second element if the first element and the second element differ from each other by an amount equal to +10% or-10%.

At time T0, the supply voltage VDDSOC transitions from the reference supply voltage VSS (e.g., 0 volts) to the voltage VW.

At time T1a, the supply voltage VDDSOC is substantially equal to the voltage VW.

Between times T1a and T1b, the supply voltage VDDSOC is substantially equal to the voltage VW.

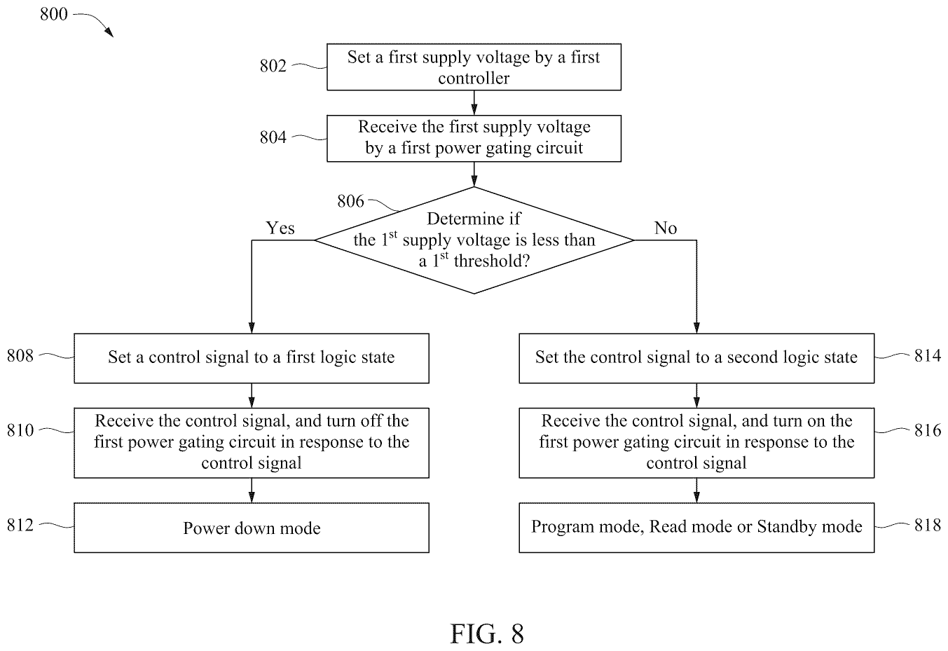

In some embodiments, between times T0 and T1b, one or more circuit elements in the integrated circuit 200 are configured in the power down, shutdown mode or sleep mode. In some embodiments, when the supply voltage VDDSOC of FIG. 2 and FIG. 8 is substantially equal to the supply voltage VDDA (e.g., voltage VL in FIG. 7), then one or more circuit elements in the integrated circuit 200 are configured in the power down, shutdown mode or sleep mode.

At time T1b, the supply voltage VDDSOC transitions from the voltage VW to the voltage VUT.

Between times T1b and T2, the supply voltage VDDSOC is substantially equal to the voltage VUT.

In some embodiments, between times T1b and T2, one or more circuit elements in the integrated circuit 200 are configured in the read mode. In some embodiments, when the supply voltage VDDSOC of FIG. 2 and FIG. 8 is substantially equal to the supply voltage VDDB (e.g., voltage VUT in FIG. 7), then one or more circuit elements in the integrated circuit 200 are configured in the read mode, standby mode or program mode.

Between times T2 and T3, the supply voltage VDDSOC is substantially equal to the voltage VUT.

In some embodiments, between times T2 and T3, one or more circuit elements in the integrated circuit 200 are configured in the standby mode.

At time T3, the supply voltage VDDSOC transitions from the voltage VUT to the voltage VL. In some embodiments, the voltage VL is less than voltage VW, and greater than reference supply voltage VSS.

Between times T3 and T4, the supply voltage VDDSOC is substantially equal to a voltage VL.

At time T4, the supply voltage VDDSOC transitions from the voltage VL to the voltage VUT.

In some embodiments, between times T3 and T4, one or more circuit elements in the integrated circuit 200 are configured in the power down, shutdown mode or sleep mode. In some embodiments, when the supply voltage VDDSOC of FIG. 2 and FIG. 8 is substantially equal to the supply voltage VDDA, then one or more circuit elements in the integrated circuit 200 are configured in the power down, shutdown mode or sleep mode.

Between time T4 and T5, the supply voltage VDDSOC is substantially equal to the voltage VUT.

In some embodiments, between times T4 and T5, one or more circuit elements in the integrated circuit 200 are configured in the program mode.

In some embodiments, after time T5, waveform 700 is repeated and is therefore similar to time T0, and similar detailed description is therefore omitted.

In some embodiments, timing diagram 700 causes at least integrated circuit 200 to achieve one or more of the benefits described herein.

In some embodiments, while timing diagram 700 is described with respect to integrated circuit 200, timing diagram 700 is also applicable to circuits 300A-300B and circuit 400 in a similar manner and is not described for brevity.

Other configurations of timing diagram 700 are within the scope of the present disclosure.

FIG. 8 is a flowchart of a method 800 of operating a circuit, in accordance with some embodiments.

In some embodiments, FIG. 8 is a flowchart of a method 800 of operating at least one of memory circuit 100 of FIG. 1, integrated circuit 200 of FIG. 2, circuit 300A of FIG. 3A, circuit 300B of FIG. 3B, circuit 400 of FIG. 4 or circuit 600 of FIG. 6, and similar detailed description is omitted for brevity.

In some embodiments, FIG. 8 is a flowchart of a method 800 of operating an integrated circuit, and the method 800 includes one or more features of timing diagram 700 of FIG. 7, and similar detailed description is omitted for brevity.

It is understood that additional operations may be performed before, during, and/or after the method 800 depicted in FIG. 8, and that some other operations may only be briefly described herein. It is understood that method 800 utilizes features of one or more of least one of memory circuit 100 of FIG. 1, integrated circuit 200 of FIG. 2, circuit 300 of FIG. 3, circuit 400 of FIG. 4, circuit 600 of FIG. 6 or timing diagram 700 of FIG. 7, and similar detailed description is omitted for brevity.

In some embodiments, other order of operations of method 800 is within the scope of the present disclosure. Method 800 includes exemplary operations, but the operations are not necessarily performed in the order shown. Operations may be added, replaced, changed order, and/or eliminated as appropriate, in accordance with the spirit and scope of disclosed embodiments. In some embodiments, one or more of the operations of method 800 is not performed.

In operation 802 of method 800, a first supply voltage is set by a first controller.

In some embodiments, the first supply voltage of method 800 includes at least supply voltage VDDSOC. In some embodiments, the first controller of method 800 includes controller 1300 of FIG. 13.

In some embodiments, the first supply voltage is set to a first voltage level or a second voltage level by the first controller. In some embodiments, the first voltage level of method 800 includes voltage VDDA. In some embodiments the second voltage level of method 800 includes voltage VDDB.

In some embodiments, operation 802 further includes setting a second supply voltage by the first controller. In some embodiments, the second supply voltage of method 800 includes at least supply voltage VQPS.

In some embodiments, operation 802 further includes adjusting the first supply voltage from the first voltage level to the second voltage level, and vice versa.

In operation 804 of method 800, the first supply voltage is received by a first power gating circuit.

In some embodiments, the first power gating circuit of method 800 includes one or more of header circuit 204, circuit 300A, circuit 300B or circuit 400. In some embodiments, the first power gating circuit of method 800 includes one or more elements of memory circuit 202.

In operation 806 of method 800, a determination is made if the first supply voltage is less than a first threshold.

In some embodiments, if the determination of operation 806 is “yes”, then method 800 proceeds to operation 808. In some embodiments, if the determination of operation 806 is “no”, then method 800 proceeds to operation 814.

In some embodiments, the first threshold of method 800 includes at least the voltage VW shown in FIG. 7.

In some embodiments, if the first supply voltage is set to the first voltage level (e.g., voltage VDDA), then the first supply voltage is less than the first threshold (e.g., voltage VW), and then method 800 proceeds to operation 808.

In some embodiments, if the first supply voltage is set to the second voltage level (e.g., voltage VDDB), then the first supply voltage is greater than or equal to the first threshold (e.g., voltage VW), and then method 800 proceeds to operation 814.

In some embodiments, operation 806 is automatically performed based on the value of the first supply voltage. In some embodiments, operation 806 is not performed.

In operation 808 of method 800, a control signal is set to a first logic state.

In some embodiments, operation 808 includes setting the control signal to the first logic state in response to the first supply voltage being less than the first threshold.

In some embodiments, the control signal of method 800 includes one or more of control signal PD1, PD2, PD3, PD4 or PD5. In some embodiments, the first logic state of method 800 is a high logic state or a logic 1.

In some embodiments, the control signal is set or adjusted by a second controller. In some embodiments, the second controller of method 800 includes controller 1300 of FIG. 13.

In operation 810 of method 800, the control signal is received by the first power gating circuit, and the first power gating circuit is turned off or disabled in response to the control signal.

In some embodiments, operation 810 includes receiving, by the first power gating circuit, the control signal and turning off or disabling the first power gating circuit in response to the first logic state of the control signal.

In some embodiments, operation 810 includes the set of inverters 302 receiving the control signal PD1, and the transistor P1 being turned off or disabled based on the logic state of at least one of control signal PD1, PD2, PD3, PD4 or PD5.

In some embodiments, operation 810 includes the set of inverters 322 receiving the control signal PD5, and the transistor P1 being turned off or disabled based on the logic state of at least one of control signal PD1, PD2, PD3, PD4 or PD5.

In operation 812 of method 800, one or more elements of memory circuit 202 enter a power down mode.

In some embodiments, the power down mode is also referred to as the shutdown mode or the sleep mode.

In operation 814 of method 800, the control signal is set to a second logic state.

In some embodiments, operation 814 includes setting the control signal to the second logic state in response to the first supply voltage being greater than or equal to the first threshold.

In some embodiments, the second logic state of method 800 is a low logic state or a logic 0.

In operation 816 of method 800, the control signal is received by the first power gating circuit, and the first power gating circuit is turned on or enabled in response to the control signal.

In some embodiments, operation 816 includes receiving, by the first power gating circuit, the control signal and turning on or enabling the first power gating circuit in response to the second logic state of the control signal.

In some embodiments, operation 816 includes the set of inverters 302 receiving the control signal PD1, and the transistor P1 being turned on or enabled based on the logic state of at least one of control signal PD1, PD2, PD3, PD4 or PD5.

In some embodiments, operation 816 includes the set of inverters 322 receiving the control signal PD5, and the transistor P1 being turned on or enabled based on the logic state of at least one of control signal PD1, PD2, PD3, PD4 or PD5.

In operation 818 of method 800, one or more elements of memory circuit 202 enter a program mode, a read mode or a standby mode.

By operating method 800, at least one of memory circuit 100 of FIG. 1, integrated circuit 200 of FIG. 2, circuit 300A of FIG. 3A, circuit 300B of FIG. 3B, circuit 400 of FIG. 4 or circuit 600 of FIG. 6 operate to achieve the benefits discussed herein.

FIG. 9 is a circuit diagram of an integrated circuit 900, in accordance with some embodiments.

In some embodiments, integrated circuit 900 is usable in FIG. 1. Integrated circuit 900 is an embodiment of circuit 120 of FIG. 1, and similar detailed description is therefore omitted.

In some embodiments, integrated circuit 900 is an embodiment of at least a portion of one or more of memory partition 102A, 102B, 102C or 102D of FIG. 1, and similar detailed description is therefore omitted. In some embodiments, integrated circuit 900 is an embodiment of memory cell array 110AR of FIG. 1, LIO circuit 110BS of FIG. 1 and WL driver circuit 110AC, and similar detailed description is therefore omitted.

Integrated circuit 900 is a variation of integrated circuit 200 of FIG. 2, and similar detailed description is therefore omitted. For example, integrated circuit 900 illustrates a non-limiting example where integrated circuit 900 further includes a set of level shifter circuits 910 and a set of level shifter circuits 920, and similar detailed description is therefore omitted.

In comparison with integrated circuit 200 of FIG. 2, integrated circuit 900 further includes the set of level shifter circuits 910 and the set of level shifter circuits 920, and similar detailed description is therefore omitted.

In comparison with integrated circuit 200 of FIG. 2, a memory circuit 902 of integrated circuit 900 replaces the memory circuit 202 of FIG. 2, and similar detailed description is therefore omitted.

Integrated circuit 900 comprises a memory circuit 902 and a set of core devices 220.

Memory circuit 902 comprises the memory circuit 202, a set of level shifter circuits 910, a set of level shifter circuits 920 and a power rail 930. In some embodiments, memory circuit 202 is not part of memory circuit 902, and similar detailed description is therefore omitted.

Memory circuit 202 comprises the header circuit 204, the power switch 206, the memory cell array 208, the bit line driver circuit 210, the word line driver circuit 212, the control circuit 214, the power rail 230 and the power rail 232.

Power rail 930 has a supply voltage VDDHV. In some embodiments, the supply voltage VDDHV is greater than the supply voltage VDDSOC, and less than the supply voltage VQPS. In some embodiments, the supply voltage VDDHV ranges from about 0.45 volts to about 1.0 volt. In some embodiments, the supply voltage VQPS ranges from about 1.5 volts to about 2.0 volts. In some embodiments, the supply voltage VQPS ranges from about 3.5 volts to about 4.5 volts. In some embodiments, the supply voltage VDDSOC ranges from about 0.45 volts to about 1.0 volt. Other supply voltage values for the supply voltage VDDHV, the supply voltage VQPS or the supply voltage VDDSOC are within the scope of the present disclosure.

Memory circuit 902 is coupled to the power rail 230 and the set of core devices 220.

Memory circuit 902 is configured to receive the supply voltage VDDSOC from power rail 230. In some embodiments, memory circuit 902 is configured to supply the supply voltage VDDSOC to the set of level shifter circuits 910 and the set of level shifter circuits 920.

In some embodiments, memory circuit 902 is configured to operate on the supply voltage VDDSOC received from the power rail 230.

In some embodiments, the supply voltage VDDSOC is adjusted from a supply voltage VDDA to a supply voltage VDDB, and vice versa. In some embodiments, the supply voltage VDDSOC is set and adjusted by a circuit, such as controller 1300 of FIG. 13. In some embodiments, the supply voltage VDDSOC is set and adjusted by a circuit, such as circuit 400 of FIG. 4. Further details of adjusting the supply voltage VDDSOC are described in at least FIG. 2, and similar detailed description is therefore omitted.

The set of level shifter circuits 910 are coupled between memory circuit 902 and memory circuit 202. In some embodiments, the set of level shifter circuits 910 are coupled between power rail 230 and power rail 930.

The set of level shifter circuits 910 is directly coupled to one or more of the memory cell array 208, bit line driver circuit 210, word line driver circuit 212, control circuit 214 or power switch 206.

In some embodiments, the set of level shifter circuits 910 includes at least one of level shifter circuit 910a, 910b or 910c. Other numbers of level shifter circuits in the set of level shifter circuit 910 are within the scope of the present disclosure.

In some embodiments, at least one level shifter circuit of the set of level shifter circuits 910 is configured to receive a set of signals S1. In some embodiments, at least one level shifter circuit of the set of level shifter circuits 910 is configured to receive the set of signals S1 from one or more of the memory cell array 208, bit line driver circuit 210, word line driver circuit 212, control circuit 214 or power switch 206.

In some embodiments, at least one level shifter circuit of the set of level shifter circuits 910 is configured to generate a set of signals S2 in response to the set of signals S1. In some embodiments, at least one level shifter circuit of the set of level shifter circuits 910 is configured to output the set of signals S2 to one or more of the memory cell array 208, bit line driver circuit 210, word line driver circuit 212, control circuit 214 or power switch 206.

In some embodiments, the set of signals S1 includes one or more of sense amplifier signal SAE1, bit line signal BL1, word line signal WL1, control signal CS1 or input data DIN1.

In some embodiments, the set of signals S2 includes one or more of sense amplifier signal SAE2, bit line signal BL2, word line signal WL2, control signal CS2 or input data DIN1.

In some embodiments, the set of signals S1 has a first voltage swing (VSS to VDDSOC), and the set of signals S2 has a second voltage swing (VSS to VDDHV). In some embodiments, the second voltage swing is different from the first voltage swing.

In some embodiments, the first voltage swing ranges from the reference supply voltage VSS to the supply voltage VDDSOC, and the second voltage swing ranges from the reference supply voltage VSS to the supply voltage VDDHV.

In some embodiments, the set of level shifter circuits 910 is coupled to the power rail 230 and the power rail 930. In some embodiments, the set of level shifter circuits 910 is configured to receive the supply voltage VDDSOC from the power rail 230 and is configured to receive the supply voltage VDDHV from the power rail 930.

The set of level shifter circuits 910 is configured to shift the set of signals S1 from the VDDSOC voltage domain that uses a supply voltage VDDSOC to the VDDHV voltage domain that uses a supply voltage VDDHV (e.g., set of signals S2). In some embodiments, the set of signals S2 are referred to as level shifted output signals.

Other configurations, elements or quantities of elements in the set of level shifter circuits 910 are within the scope of the present disclosure. In some embodiments, at least one level shifter circuit of the set of level shifter circuits 910 is replaced by one or more of a charge pump circuit or a boost circuit.

The set of level shifter circuits 920 are coupled between memory circuit 202 and memory circuit 902. In some embodiments, the set of level shifter circuits 920 are coupled between power rail 930 and power rail 230.

The set of level shifter circuits 920 is directly coupled to one or more of the memory cell array 208, bit line driver circuit 210, word line driver circuit 212, control circuit 214 or power switch 206.

In some embodiments, the set of level shifter circuits 920 includes at least one of level shifter circuit 920a, 920b or 920c. Other numbers of level shifter circuits in the set of level shifter circuit 920 are within the scope of the present disclosure.

In some embodiments, at least one level shifter circuit of the set of level shifter circuits 920 is configured to receive a set of signals C1. In some embodiments, at least one level shifter circuit of the set of level shifter circuits 920 is configured to receive the set of signals C1 from one or more of the memory cell array 208, bit line driver circuit 210, word line driver circuit 212, control circuit 214 or power switch 206.

In some embodiments, at least one level shifter circuit of the set of level shifter circuits 920 is configured to generate a set of signals C2 in response to the set of signals C1. In some embodiments, at least one level shifter circuit of the set of level shifter circuits 920 is configured to output the set of signals C2 to one or more of the memory cell array 208, bit line driver circuit 210, word line driver circuit 212, control circuit 214 or power switch 206.

In some embodiments, the set of signals C1 includes one or more of sense amplifier signal SAE1, bit line signal BL1, word line signal WL1, control signal CC1 or input data DIN1.

In some embodiments, the set of signals C2 includes one or more of sense amplifier signal SAE2, bit line signal BL2, word line signal WL2, control signal CC2 or input data DIN1.

In some embodiments, the set of signals C1 have the second voltage swing (VSS to VDDHV), and the set of signals C2 have the first voltage swing (VSS to VDDSOC).

In some embodiments, the set of level shifter circuits 920 is coupled to the power rail 930 and the power rail 230. In some embodiments, the set of level shifter circuits 920 is configured to receive the supply voltage VDDSOC from the power rail 230 and is configured to receive the supply voltage VDDHV from the power rail 930.

The set of level shifter circuits 920 is configured to shift the set of signals C1 from the VDDHV voltage domain that uses a supply voltage VDDHV to the VDDSOC voltage domain that uses a supply voltage VDDSOC (e.g., set of signals C2). In some embodiments, the set of signals C2 are referred to as level shifted output signals.

Other configurations, elements or quantities of elements in the set of level shifter circuits 920 are within the scope of the present disclosure. In some embodiments, at least one level shifter circuit of the set of level shifter circuits 920 is replaced by one or more of a low-dropout (LDO) regulator circuit or a buck circuit.

As shown in FIG. 9, memory circuit 202 is coupled to power rails 930 and 232, and the set of level shifter circuits 910 and 920.

As shown in FIG. 9, memory circuit 202 is configured to receive the supply voltage VDDHV from power rail 930, and to receive the supply voltage VQPS from power rail 232.

In some embodiments, memory circuit 202 of FIG. 9 is configured to operate on the supply voltage VDDHV received from the power rail 930 or the supply voltage VQPS received from the power rail 232.

As shown in FIG. 9, header circuit 204 is coupled to the power rail 930. As shown in FIG. 9, header circuit 204 is configured to receive the supply voltage VDDHV from the power rail 930. As shown in FIG. 9, header circuit 204 is configured to supply the supply voltage VDDHV to at least node ND1.

In some embodiments, as shown in FIG. 9, header circuit 204 is configured to supply the supply voltage VDDHV to at least one of memory cell array 208, bit line driver circuit 210, word line driver circuit 212 or control circuit 214 in response to a control signal PD1 (e.g., FIG. 3A) or a control signal PD5 (e.g., FIG. 3B). In some embodiments, header circuit 204 is also referred to as a power gating circuit.

As shown in FIG. 9, header circuit 204 is further coupled to one or more of memory cell array 208, bit line driver circuit 210, word line driver circuit 212 or control circuit 214 by the node ND1. In some embodiments, as shown in FIG. 9, header circuit 204 is configured to supply the supply voltage VDDHV to at least one of memory cell array 208, bit line driver circuit 210, word line driver circuit 212 or control circuit 214 by node ND1.

In some embodiments, as shown in FIG. 9, at least one of memory cell array 208, bit line driver circuit 210, word line driver circuit 212 or control circuit 214 is configured to operate on the supply voltage VDDHV received from the header circuit 204.

Other configurations, elements or quantities of elements in header circuit 204 are within the scope of the present disclosure.

As shown in FIG. 9, memory cell array 208 is configured to receive the supply voltage VDDHV from the header circuit 204 by the node ND1.

Other configurations, elements or quantities of elements in memory cell array 208 are within the scope of the present disclosure.

As shown in FIG. 9, the bit line driver circuit 210 is configured to receive the supply voltage VDDHV.

Other configurations, elements or quantities of elements in bit line driver circuit 210 are within the scope of the present disclosure.

As shown in FIG. 9, the word line driver circuit 212 is configured to receive the supply voltage VDDHV.

Other configurations, elements or quantities of elements in word line driver circuit 212 are within the scope of the present disclosure.

As shown in FIG. 9, the control circuit 214 is configured to receive the supply voltage VDDHV.

In some embodiments, as shown in FIG. 9, the sense amplifier circuit 214a is configured to receive the supply voltage VDDHV.

In some embodiments, the control circuit 214 includes other types of circuits. In some embodiments, the control circuit 214 includes at least one level shifter circuit similar to the set of level shifter circuits 910 or 920, and similar detailed description is therefore omitted.

Other configurations, elements or quantities of elements in control circuit 214 or sense amplifier circuit 214a are within the scope of the present disclosure.

Other configurations, elements or quantities of elements in memory circuit 202 are within the scope of the present disclosure.

In some embodiments, at least one of the transistors in at least one of the set of level shifter circuits 910 or the set of level shifter circuits 920 has the threshold voltage VT1. In some embodiments, at least one of the transistors in the header circuit 204, the memory cell array 208, the bit line driver circuit 210, the word line driver circuit 212, the sense amplifier 214a of control circuit 214 or the power switch 206 has the threshold voltage VT2. In some embodiments, the threshold voltage VT2 is greater than the threshold voltage VT1.

In some embodiments, by configuring one of the set of level shifter circuits 910 or the set of level shifter circuits 920 to have different threshold voltages from memory circuit 202 allows the set of core circuits 220 and memory circuit 902 to operate at lower voltage ranges than memory circuit 202 thereby reducing the power consumption of at least the set of core circuits 220 compared to other approaches.

In some embodiments, by configuring the memory circuit 202 with a header circuit 204 reduces the leakage current in the path including node ND1 when one or more of memory cell array 208, bit line driver circuit 210, word line driver circuit 212, control circuit 214 or power switch 206 is disabled or is in sleep mode (e.g., power down mode), thereby reducing the power consumption of integrated circuit 900 compared with other approaches that have higher leakage current and greater power consumption.

In some embodiments, integrated circuit 900 achieves one or more of the benefits described herein.

Other configurations, elements or quantities of elements in integrated circuit 900 are within the scope of the present disclosure.

FIG. 10 is a circuit diagram of a level shifter circuit 1000, in accordance with some embodiments.

Level shifter circuit 1000 is an embodiment of one or more level shifter circuits 910a, 910b or 910c in the set of level shifter circuits 910, and similar detailed description is omitted.

Level shifter circuit 1000 is an embodiment of one or more level shifter circuits 920a, 920b or 920c in the set of level shifter circuits 920, and similar detailed description is omitted.

Level shifter circuit 1000 is configured to receive a signal LSin, and to generate a signal LSout. Level shifter circuit 1000 is a level shifter circuit configured to shift signals from a first voltage domain VXX that uses supply voltage VXX1 to a second voltage domain VYY that uses supply voltage VYY1.

In some embodiments, the first voltage domain VXX is voltage domain VDD, the supply voltage VXX1 is supply voltage VDD1, the second voltage domain VYY is voltage domain VDDM, and the supply voltage VYY1 is supply voltage VDDM1, and level shifter circuit 1000 is configured to shift signals from voltage domain VDD that uses supply voltage VDD1 to voltage domain VDDM that uses supply voltage VDDM1. For example, in these embodiments, level shifter circuit 1000 is an embodiment of one or more level shifter circuits 910a, 910b or 910c in the set of level shifter circuits 910, and similar detailed description is omitted. For example, in these embodiments, when level shifter circuit 1000 is an embodiment of one or more level shifter circuits 910a, 910b or 910c in the set of level shifter circuits 910, signal LSin corresponds to one or more of sense amplifier signal SAE1, bit line signal BL1, word line signal WL1, control signal CS1 or input data DIN1, and signal LSout corresponds to one or more of bit line signal BL2, word line signal WL2, control signal CS2 or input data DIN1.

In some embodiments, the voltage domain VDD includes the supply voltage VDDSOC, and the voltage domain VDDM includes the supply voltage VDDHV, and similar detailed description is therefore omitted.

In some embodiments, the first voltage domain VXX is voltage domain VDDM, the supply voltage VXX1 is supply voltage VDDM1, the second voltage domain VYY is voltage domain VDD, and the supply voltage VYY1 is supply voltage VDD1, and level shifter circuit 1000 is configured to shift signals from voltage domain VDDM that uses supply voltage VDDM1 to voltage domain VDD that uses supply voltage VDD1. For example, in these embodiments, level shifter circuit 1000 is an embodiment of one or more level shifter circuits 920a, 920b or 920c in the set of level shifter circuits 920, and similar detailed description is omitted. For example, in these embodiments, when level shifter circuit 1000 is an embodiment of one or more level shifter circuits 920a, 920b or 920c of the set of level shifter circuits 920, signal LSin corresponds to one or more of sense amplifier signal SAE2, bit line signal BL1, word line signal WL1, control signal CS1 or input data DIN1, and signal LSout corresponds to one or more of bit line signal BL2, word line signal WL2, control signal CS2 or input data DIN1.

Level shifter circuit 1000 is configured to receive signal LSin on an input terminal (not labelled), and to output a signal LSout on an output terminal (not labeled). Signal LSin corresponds to an input signal of level shifter circuit 1000, and signal LSout corresponds to an output signal of level shifter circuit 1000. Level shifter circuit 1000 is configured to generate signal LSout based on signal LSin.

Signal LSout corresponds to a level shifted version of signal LSin. In some embodiments, a voltage level of signal LSin of level shifter circuit 1000 is less than a voltage level of the signal LSout of level shifter circuit 1000. In some embodiments, the voltage level of signal LSin of level shifter circuit 1000 is greater than the voltage level of signal LSout of level shifter circuit 1000.

Level shifter circuit 1000 includes an inverter 1002, an NMOS transistor 1004, a PMOS transistor 1006, a PMOS transistor 1008, a PMOS transistor 1010, a PMOS transistor 1012, an NMOS transistor 1014 and an inverter 1016.

An input terminal of inverter 1002 is configured to receive a signal LSin. Each of the input terminal of inverter 1002, a gate terminal of PMOS transistor 1006, and a gate terminal of NMOS transistor 1004 are coupled to each other. An output terminal of inverter 1002 is configured to output a signal LSBin. In some embodiments, signal LSBin is an inverted version of signal LSin. Inverter 1002 is configured to generate signal LSBin based on signal CKPI. Inverter 1002 is coupled to voltage supply VXX. In some embodiments, inverter 1002 is a CMOS inverter type coupled to voltage supply VXX and reference voltage supply VSS.

The gate terminal of NMOS transistor 1004 is configured to receive signal LSin. A source terminal of NMOS transistor 1004 is coupled to reference voltage supply VSS. Each of a drain terminal of NMOS transistor 1004, a drain terminal of PMOS transistor 1006, a gate terminal of PMOS transistor 1010, and an input terminal of inverter 1016 are coupled together at a node 10-N1.

The gate terminal of PMOS transistor 1006 is configured to receive signal LSin. A source terminal of PMOS transistor 1006 is coupled to the drain terminal of PMOS transistor 1008.

A source terminal of PMOS transistor 1008 is coupled with voltage supply VYY. Each of a gate terminal of PMOS transistor 1008, a drain terminal of NMOS transistor 1014, and a drain terminal of PMOS transistor 1012 are coupled to each other at a node 10-N2. The gate terminal of PMOS transistor 1008 is configured to receive a voltage at node 10-N2. In some embodiments, PMOS transistor 1008 is turned on or off based on the voltage at node 10-N2.

NMOS transistor 1004, PMOS transistor 1006 and PMOS transistor 1008 are configured to set the voltage of node 10-N1 which corresponds to signal LSBout. For example, in some embodiments, if NMOS transistor 1004 is turned on, NMOS transistor 1004 is configured to pull node 10-N1 towards reference voltage VSS. For example, in some embodiments, if PMOS transistors 1006 and 1008 are turned on, PMOS transistors 1006 and 1008 are configured to pull node 10-N1 towards supply voltage VYY1.

A source terminal of PMOS transistor 1010 is coupled with voltage supply VYY. A drain terminal of PMOS transistor 1010 is coupled with a source terminal of PMOS transistor 1012. The gate terminal of PMOS transistor 1010 is coupled to at least node 10-N1. A voltage at node 10-N1 corresponds to a signal LSBout. The gate terminal of PMOS transistor 1010 is configured to receive signal LSBout. In some embodiments, PMOS transistor 1010 is turned on or off based on the voltage at node 10-N1 which corresponds to signal LSBout.

The gate terminal of PMOS transistor 1012 is configured to receive signal LSBin from inverter 1002. Each of the gate terminal of PMOS transistor 1012, a gate terminal of NMOS transistor 1014 and the output terminal of inverter 1002 are coupled to each other.

The gate terminal of NMOS transistor 1014 is configured to receive signal LSBin from inverter 1002. A source terminal of NMOS transistor 1014 is coupled to reference voltage supply VSS.

NMOS transistor 1014, PMOS transistor 1010 and PMOS transistor 1012 are configured to set the voltage of node 10-N1 which corresponds to signal LSBout. For example, in some embodiments, if NMOS transistor 1014 is turned on, NMOS transistor 1014 is configured to pull node 10-N2 towards reference voltage VSS. For example, in some embodiments, if PMOS transistors 1010 and 1012 are turned on, PMOS transistors 1010 and 1012 are configured to pull node 10-N2 towards supply voltage VYY1.

The input terminal of inverter 1016 is configured to receive signal LSBout from node 10-N1. An output terminal of inverter 1016 is configured to output signal LSout. In some embodiments, signal LSout is an inverted version of signal LSBout. Inverter 1016 is configured to generate signal LSout based on signal LSBout. Inverter 1016 is coupled to voltage supply VYY. In some embodiments, inverter 1016 is a CMOS inverter type coupled to voltage supply VYY and reference voltage VSS. Signal LSout corresponds to the output signal of level shifter circuit 1000. Signal LSout is a level shifted version of signal LSin.

Other configurations and types of level shifters for level shifter circuit 1000 are within the scope of the present disclosure.

In some embodiments, level shifter circuit 1000 achieves one or more of the benefits described herein.

Other configurations, elements or quantities of elements in level shifter circuit 1000 are within the scope of the present disclosure.

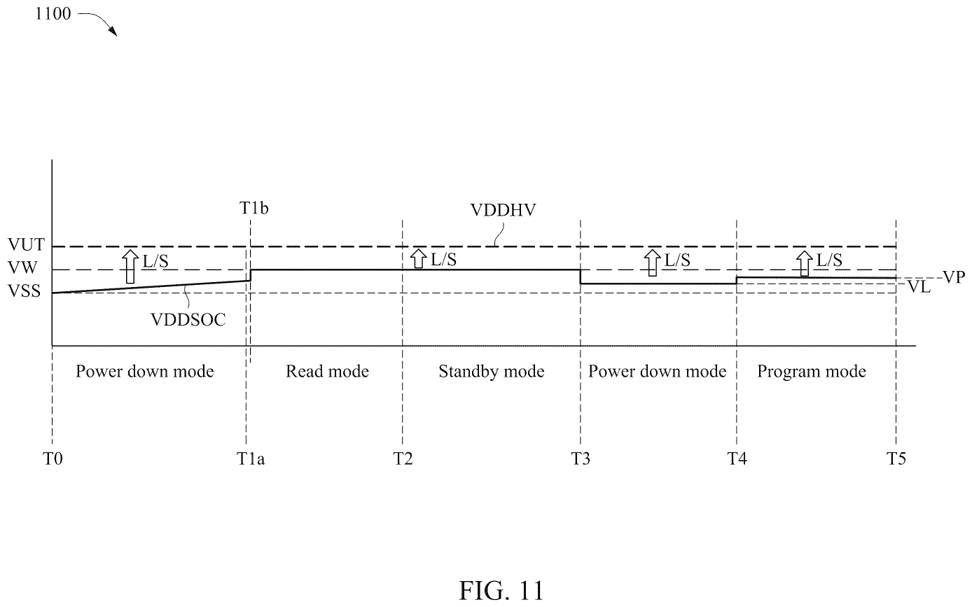

FIG. 11 is a timing diagram 1100 of waveforms of an integrated circuit, in accordance with some embodiments.

In some embodiments, FIG. 11 is a timing diagram 1100 of waveforms of integrated circuit 900 in FIG. 9.

In some embodiments, one or more power down operations, standby operations, read operations, write/program operations are applied to a memory cell in memory cell array 208 of FIG. 9 or at least one memory cell in a single column of memory cell array 110AR of FIG. 1, and timing diagram 1100 corresponds to waveforms during the one or more power down operations, standby operations, read operations or write/program operations of memory cell array 208 of FIG. 9 or at least one memory cell in a single column of memory cell array 110AR of FIG. 1.

In some embodiments, one or more power down operations, standby operations, read operations or write/program operations of the memory banks in at least memory circuit 100 of FIG. 1 are applied to at least one of memory partition 102A, 102B, 102C or 102D, and timing diagram 1100 corresponds to waveforms during the one or more power down operations, standby operations, read operations or write/program operations of at least one of memory partition 102A, 102B, 102C or 102D.

Timing diagram 1100 includes waveforms of the supply voltage VDDSOC, a supply voltage VDDHV or the supply voltage VDDHV. In some embodiments, the supply voltage VDDHV is substantially equal to a voltage level (e.g., voltage VUT). In some embodiments, the supply voltage VDDSOC ranges from about the reference voltage supply VSS to about voltage VW.

In some embodiments, the voltage VUT is greater than the voltage VW. In some embodiments, the voltage VUT is a voltage of one or more circuit elements in the integrated circuit 900, and similar detailed description is therefore omitted. In some embodiments, the voltage VW is a working voltage of one or more circuit elements in the integrated circuit 900, and similar detailed description is therefore omitted. In some embodiments, the voltage VW is a threshold voltage of one or more circuit elements in the integrated circuit 900, and similar detailed description is therefore omitted.

In some embodiments, the voltage VUT ranges from about 0.6 volts to about 2.0 volts. In some embodiments, the voltage VW ranges from about 0.4 volts to about 1.8 volts.

From time T0 to time T5, the supply voltage VDDHV is substantially equal to the voltage VUT. In some embodiments, the supply voltage VDDHV is a level shifted version of the supply voltage VDD SOC, and is represented in FIG. 11 by “L/S”, and similar detailed description is therefore omitted

Prior to time T0, the supply voltage VDDSOC is substantially equal to the reference supply voltage VSS (e.g., 0 volts).

At time T0, the supply voltage VDDSOC transitions from the reference supply voltage VSS (e.g., 0 volts) to the voltage VL.

At time T1a, the supply voltage VDDSOC is substantially equal to the voltage VL.

Between times T1a and T1b, the supply voltage VDDSOC transitions from the voltage VL to the voltage VW.

In some embodiments, between times T0 and T1b, one or more circuit elements in the integrated circuit 900 are configured in the power down, shutdown mode or sleep mode. In some embodiments, when the supply voltage VDDSOC of FIG. 9 and FIG. 8 is substantially equal to the supply voltage VDDA (e.g., voltage VL in FIG. 11), then one or more circuit elements in the integrated circuit 900 are configured in the power down, shutdown mode or sleep mode.

At time T1B, the supply voltage VDDSOC is substantially equal to the voltage VW.

Between times T1b and T2, the supply voltage VDDSOC is substantially equal to the voltage VW.

In some embodiments, between times T1b and T2, one or more circuit elements in the integrated circuit 900 are configured in the read mode. In some embodiments, when the supply voltage VDDSOC of FIG. 9 and FIG. 8 is substantially equal to the supply voltage VDDB (e.g., voltage VW in FIG. 7), then one or more circuit elements in the integrated circuit 900 are configured in the read mode, standby mode or program mode.

Between times T2 and T3, the supply voltage VDDSOC is substantially equal to the voltage VW.

In some embodiments, between times T2 and T3, one or more circuit elements in the integrated circuit 900 are configured in the standby mode.

At time T3, the supply voltage VDDSOC transitions from the voltage VW to the voltage VL. In some embodiments, the voltage VL is less than voltage VW, and greater than the reference supply voltage VSS.

Between times T3 and T4, the supply voltage VDDSOC is substantially equal to a voltage VL.

At time T4, the supply voltage VDDSOC transitions from the voltage VL to a voltage VP. In some embodiments, the voltage VP is greater than the voltage VL, and less than the voltage VW.

In some embodiments, between times T3 and T4, one or more circuit elements in the integrated circuit 900 are configured in the power down, shutdown mode or sleep mode. In some embodiments, when the supply voltage VDDSOC of FIG. 9 and FIG. 8 is substantially equal to the supply voltage VDDA, then one or more circuit elements in the integrated circuit 900 are configured in the power down, shutdown mode or sleep mode.

Between time T4 and T5, the supply voltage VDDSOC is substantially equal to the voltage VP. In some embodiments, between time T4 and T5, the supply voltage VDDSOC is substantially equal to the voltage VW.

In some embodiments, between times T4 and T5, one or more circuit elements in the integrated circuit 900 are configured in the program mode.

In some embodiments, after time T5, waveform 1100 is repeated and is therefore similar to time T0, and similar detailed description is therefore omitted.

In some embodiments, timing diagram 1100 causes at least integrated circuit 900 to achieve one or more of the benefits described herein.

In some embodiments, while timing diagram 1100 is described with respect to integrated circuit 900, timing diagram 1100 is also applicable to circuits 300A-300B and circuit 400 in a similar manner and is not described for brevity.

Other configurations of timing diagram 1100 are within the scope of the present disclosure.

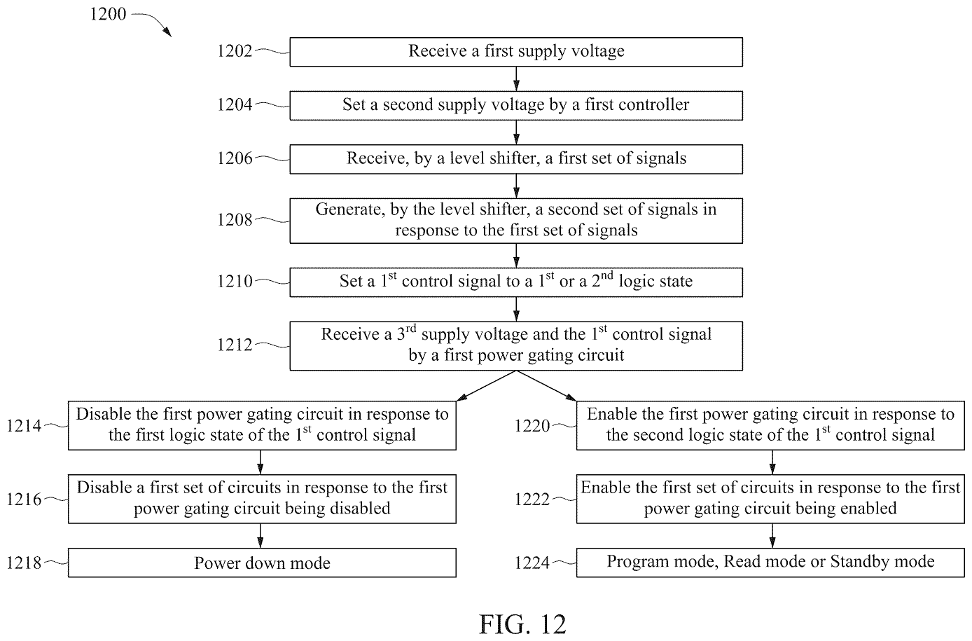

FIG. 12 is a flowchart of a method 1200 of operating a circuit, in accordance with some embodiments.

In some embodiments, FIG. 12 is a flowchart of a method 1200 of operating integrated circuit 900 of FIG. 9, and similar detailed description is omitted for brevity.

In some embodiments, FIG. 12 is a flowchart of a method 1200 of operating at least one of memory circuit 100 of FIG. 1, circuit 300A of FIG. 3A, circuit 300B of FIG. 3B, circuit 400 of FIG. 4 or circuit 600 of FIG. 6, and similar detailed description is omitted for brevity.

In some embodiments, FIG. 12 is a flowchart of a method 1200 of operating an integrated circuit, and the method 1200 includes one or more features of timing diagram 1100 of FIG. 11, and similar detailed description is omitted for brevity.

It is understood that additional operations may be performed before, during, and/or after the method 1200 depicted in FIG. 12, and that some other operations may only be briefly described herein. It is understood that method 1200 utilizes features of one or more of least one of memory circuit 100 of FIG. 1, integrated circuit 900 of FIG. 9, circuit 300A of FIG. 3A, circuit 300B of FIG. 3B, circuit 400 of FIG. 4, circuit 600 of FIG. 6, eFuse circuits 500A-500B or level shifter circuit 1000 of FIG. 10, and similar detailed description is omitted for brevity.

In some embodiments, other order of operations of method 1200 is within the scope of the present disclosure. Method 1200 includes exemplary operations, but the operations are not necessarily performed in the order shown. Operations may be added, replaced, changed order, and/or eliminated as appropriate, in accordance with the spirit and scope of disclosed embodiments. In some embodiments, one or more of the operations of method 1200 is not performed.

In operation 1202 of method 1200, a first supply voltage is received from a first power rail.

In some embodiments, the first supply voltage of method 1200 includes at least supply voltage VQPS. In some embodiments, the first power rail of method 1200 includes at least power rail 232.

In some embodiments, the first supply voltage of method 1200 is received by memory circuit 202.

In operation 1204 of method 1200, a second supply voltage of a second power rail is set or adjusted by a first controller.

In some embodiments, the second supply voltage of method 1200 includes at least supply voltage VDDSOC. In some embodiments, the second power rail of method 1200 includes at least power rail 230. In some embodiments, the first controller of method 1200 includes controller 1300 of FIG. 13.

In some embodiments, the second supply voltage is set to a first voltage level or a second voltage level by the first controller. In some embodiments, the first voltage level of method 1200 includes voltage VDDA. In some embodiments the second voltage level of method 1200 includes voltage VDDB.

In some embodiments, operation 1202 further includes adjusting the second supply voltage from the first voltage level to the second voltage level, and vice versa.

In operation 1206 of method 1200, a first set of signals is received by a set of level shifter circuits.

In some embodiments, the set of level shifter circuits is coupled between the second power rail and a third power rail. In some embodiments, the third power rail has a third supply voltage.

In some embodiments, the third power rail of method 1200 includes at least power rail 930. In some embodiments, the third supply voltage of method 1200 includes at least supply voltage VDDHV.

In some embodiments, the first set of signals of method 1200 includes one or more of sense amplifier signal SAE1, bit line signal BL1, word line signal WL1, control signal CS1 or input data DIN1.

In operation 1208 of method 1200, a second set of signals is generated by the set of level shifter circuits in response to the first set of signals.

In some embodiments, the second set of signals of method 1200 includes one or more of sense amplifier signal SAE2, bit line signal BL2, word line signal WL2, control signal CS2 or input data DIN1.

In some embodiments, the first set of signals have a first voltage swing (VSS to VDDSOC), and the second set of signals have a second voltage swing (VSS to VDDHV). In some embodiments, the second voltage swing is different from the first voltage swing.

In some embodiments, the first voltage swing ranges from the reference supply voltage VSS to the supply voltage VDDSOC, and the second voltage swing ranges from the reference supply voltage VSS to the supply voltage VDDHV.

In some embodiments, the second voltage swing ranges from the reference supply voltage VSS to the supply voltage VDDSOC, and the first voltage swing ranges from the reference supply voltage VSS to the supply voltage VDDHV.

In operation 1210 of method 1200, a first control signal is set to a first logic state or a second logic state. In some embodiments, the second logic state is different from the first logic state.

In some embodiments, operation 1210 includes setting the first control signal to the first logic state in response to the first supply voltage being less than a first threshold.

In some embodiments, operation 1210 includes setting the first control signal to the second logic state in response to the first supply voltage being greater than or equal to the first threshold.

In some embodiments, the first threshold of method 1200 includes at least the voltage VW shown in FIG. 11.

In some embodiments, if the first supply voltage is set to the first voltage level (e.g., voltage VDDA), then the first supply voltage is less than the first threshold (e.g., voltage VW), and then operation 1210 includes setting the first control signal to the first logic state.

In some embodiments, if the first supply voltage is set to the second voltage level (e.g., voltage VDDB), then the first supply voltage is greater than or equal to the first threshold (e.g., voltage VW), and then operation 1210 includes setting the first control signal to the second logic state.

In some embodiments, the first control signal of method 1200 includes one or more of control signal PD1, PD2, PD3, PD4 or PD5. In some embodiments, the first logic state of method 1200 is a high logic state or a logic 1. In some embodiments, the second logic state of method 1200 is a low logic state or a logic 0.

In some embodiments, first the control signal is set or adjusted by a second controller. In some embodiments, the second controller of method 1200 includes controller 1300 of FIG. 13.

In operation 1212 of method 1200, the third supply voltage and the first control signal is received by a first power gating circuit. In some embodiments, the first power gating circuit is coupled between the third power rail and a first node.

In some embodiments, the first power gating circuit of method 1200 includes one or more of header circuit 204, circuit 300A, circuit 300B or circuit 400. In some embodiments, the first power gating circuit of method 1200 includes one or more elements of memory circuit 902 or 202.

In some embodiments, the first node of method 1200 includes node ND1.

In some embodiments, if the first control signal is set to the first logic state, then method 1200 proceeds to operation 1214. In some embodiments, if the first control signal is set to the second logic state, then method 1200 proceeds to operation 1220.

In operation 1214 of method 1200, the first power gating circuit is turned off or disabled in response to the first control signal.

In some embodiments, operation 1214 includes receiving, by the first power gating circuit, the first control signal and turning off or disabling the first power gating circuit in response to the first logic state of the first control signal.

In some embodiments, operation 1214 includes the set of inverters 302 receiving the control signal PD1, and the transistor P1 being turned off or disabled based on the logic state of at least one of control signal PD1, PD2, PD3, PD4 or PD5.

In some embodiments, operation 1214 includes the set of inverters 322 receiving the control signal PD5, and the transistor P1 being turned off or disabled based on the logic state of at least one of control signal PD1, PD2, PD3, PD4 or PD5.

In operation 1216 of method 1200, a first set circuits is turned off or disabled in response to the first power gating circuit being disabled or turned off.

In some embodiments, the first set circuits of method 1200 includes one or more of header circuit 204, power switch 206, memory cell array 208, bit line driver circuit 210, word line driver circuit 212, control circuit 214, the set of level shifter circuits 910 or the set of level shifter circuits 912.

In some embodiments, the first set circuits of method 1200 includes one or more circuits of memory circuit 202 or 902.

In operation 1218 of method 1200, one or more elements of memory circuit 202 or 902 enter a power down mode.

In some embodiments, the power down mode is also referred to as the shutdown mode or the sleep mode.

In operation 1220 of method 1200, the first power gating circuit is turned on or enabled in response to the first control signal.

In some embodiments, operation 1220 includes receiving, by the first power gating circuit, the first control signal and turning on or enabling the first power gating circuit in response to the second logic state of the first control signal.

In some embodiments, operation 1220 includes the set of inverters 302 receiving the control signal PD1, and the transistor P1 being turned on or enabled based on the logic state of at least one of control signal PD1, PD2, PD3, PD4 or PD5.

In some embodiments, operation 1214 includes the set of inverters 322 receiving the control signal PD5, and the transistor P1 being turned on or enabled based on the logic state of at least one of control signal PD1, PD2, PD3, PD4 or PD5.

In operation 1222 of method 1200, the first set circuits is turned on or enabled in response to the first power gating circuit being enabled or turned on.

In operation 1224 of method 1200, one or more elements of memory circuit 202 or 902 enter a program mode, a read mode or a standby mode.

By operating method 1200, at least one of memory circuit 100 of FIG. 1, integrated circuit 900 of FIG. 9, circuit 300A of FIG. 3A, circuit 300B of FIG. 3B, circuit 400 of FIG. 4 or circuit 600 of FIG. 6 operate to achieve the benefits discussed herein.

FIG. 13 is a schematic view of a controller 1300 for generating one or more control signals or voltages, in accordance with some embodiments.

In some embodiments, controller 1300 is usable in one or more of the memory circuit 100 of FIG. 1, integrated circuit 200 of FIG. 2, circuit 300A of FIG. 3A, circuit 300B of FIG. 3B, circuit 400 of FIG. 4, eFuse circuits 500A-500B of FIGS. 5A-5B, circuit 600 of FIG. 6, integrated circuit 900 of FIG. 9, timing diagram 700 of FIG. 7, timing diagram 1100 of FIG. 11, method 800 of FIG. 8, method 1200 of FIG. 12, and similar detailed description is omitted for brevity.

In some embodiments, controller 1300 is useable to generate or set one or more of the supply voltage VDDA, the supply voltage VDDB, the supply voltage VDDSOC, voltage VL, and similar detailed description is omitted for brevity.

In some embodiments, controller 1300 is useable to generate or set one or more of the control signal PD1, control signal PD5, control signal PS1 or control signal PS1B, and similar detailed description is omitted for brevity.

Controller 1300 includes a hardware processor 1302 and a non-transitory, computer readable storage medium 1304 encoded with, i.e., storing, the computer program code 1306, i.e., a set of executable instructions. Computer readable storage medium 1304 is also encoded with instructions 1306 for interfacing with at least one of memory circuit 100 of FIG. 1, integrated circuit 200 of FIG. 2, circuit 300A of FIG. 3A, circuit 300B of FIG. 3B, circuit 400 of FIG. 4, eFuse circuits 500A-500B of FIGS. 5A-5B, circuit 600 of FIG. 6 or integrated circuit 900 of FIG. 9.

The processor 1302 is electrically coupled to the computer readable storage medium 1304 by a bus 1308. The processor 1302 is also electrically coupled to an I/O interface 1310 by bus 1308. A network interface 1312 is also electrically connected to the processor 1302 by bus 1308. Network interface 1312 is connected to a network 1314, so that processor 1302 and computer readable storage medium 1304 are capable of connecting to external elements via network 1314. The processor 1302 is configured to execute the computer program code 1306 encoded in the computer readable storage medium 1304 in order to cause controller 1300 to be usable for performing a portion or all of the operations as described in at least one of method 800 or 1200 or timing diagrams 700 or 1100.

In some embodiments, the processor 1302 is a central processing unit (CPU), a multi-processor, a distributed processing system, an application specific integrated circuit (ASIC), and/or a suitable processing unit.

In some embodiments, the computer readable storage medium 1304 is an electronic, magnetic, optical, electromagnetic, infrared, and/or a semiconductor system (or apparatus or device). For example, the computer readable storage medium 1304 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 1304 includes a compact disk-read only memory (CD-ROM), a compact disk-read/write (CD-R/W), and/or a digital video disc (DVD).

In some embodiments, the storage medium 1304 stores the computer program code 1306 configured to cause controller 1300 to perform at least one of method 800 or 1200 or timing diagrams 700 or 1100. In some embodiments, the storage medium 1304 also stores information needed for performing at least one of method 800 or 1200 or timing diagrams 700 or 1100 as well as information generated during performance of at least one of method 800 or 1200 or timing diagrams 700 or 1100, such as control signals 1316 or voltages 1318, and/or a set of executable instructions to perform the operation of at least one of method 800 or 1200 or timing diagrams 700 or 1100.

In some embodiments, the storage medium 1304 stores instructions (e.g., computer program code 1306) for interfacing with one or more of memory circuit 100 of FIG. 1, integrated circuit 200 of FIG. 2, circuit 300A of FIG. 3A, circuit 300B of FIG. 3B, circuit 400 of FIG. 4, eFuse circuits 500A-500B of FIGS. 5A-5B, circuit 600 of FIG. 6, integrated circuit 900 of FIG. 9. The instructions (e.g., computer program code 1306) enable processor 1302 to generate instructions to control the memory circuit 100 of FIG. 1, integrated circuit 200 of FIG. 2, circuit 300A of FIG. 3A, circuit 300B of FIG. 3B, circuit 400 of FIG. 4, eFuse circuits 500A-500B of FIGS. 5A-5B, circuit 600 of FIG. 6, integrated circuit 900 of FIG. 9 to effectively implement at least one of method 800 or 1200 or timing diagrams 700 or 1100.

Controller 1300 includes I/O interface 1310. I/O interface 1310 is coupled to external circuitry. In some embodiments, I/O interface 1310 includes a keyboard, keypad, mouse, trackball, trackpad, and/or cursor direction keys for communicating information and commands to processor 1302.

Controller 1300 also includes network interface 1312 coupled to the processor 1302. Network interface 1312 allows controller 1300 to communicate with network 1314, to which one or more other computer systems are connected. Network interface 1312 includes wireless network interfaces such as BLUETOOTH, WIFI, WIMAX, GPRS, or WCDMA; or wired network interface such as ETHERNET, USB, or IEEE-13104. In some embodiments, at least one of method 800 or 1200 or timing diagrams 700 or 1100 is implemented in two or more systems 1300, and information such as reference signal, scrambled signal, clock output signal, duty cycle signals, comparator output signal, set of control signals, selection signal or FSM signals are exchanged between different systems 1300 by network 1314.

Controller 1300 is configured to receive information related to a reference signal through I/O interface 1310 or network interface 1312. The information is transferred to processor 1302 by bus 1308 to generate control signals. The reference signal is then stored in computer readable medium 1304 as control signals 1316.

Controller 1300 is configured to receive information related to voltages through I/O interface 1310 or network interface 1312. The information is stored in computer readable medium 1304 as voltages 1318.

In some embodiments, control signals 1316 includes one or more of the control signal PD1, control signal PD5, control signal PS1 or control signal PS1B. In some embodiments, control signals 1316 includes one or more of the signals described herein.

In some embodiments, voltages 1318 includes one or more of the supply voltage VDDA, the supply voltage VDDB, the supply voltage VDDSOC, voltage VL.

In some embodiments, voltages 1318 includes one or more of the supply voltages described herein.

In some embodiments, one or more of the operations of method 800 or 1200 is not performed. Furthermore, various PMOS or NMOS transistors shown in the present disclosure are of a particular dopant type (e.g., N-type or P-type) are for illustration purposes. Embodiments of the present disclosure are not limited to a particular transistor type, and one or more of the PMOS or NMOS transistors shown in the present disclosure can be substituted with a corresponding transistor of a different transistor/dopant type. Similarly, the low or high logical value of various signals used in the above description is also for illustration. Embodiments of the disclosure are not limited to a particular logical value when a signal is activated and/or deactivated. Selecting different logical values is within the scope of various embodiments. Selecting different numbers of inverters in the present disclosure is within the scope of various embodiments. Selecting different numbers of transistors in the present disclosure is within the scope of various embodiments.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

One aspect of this description relates to an integrated circuit. In some embodiments, the integrated circuit includes a first power rail configured to supply a first supply voltage. In some embodiments, the integrated circuit further includes a second power rail configured to supply a second supply voltage different from the first supply voltage, the second supply voltage having a first value or a second value different from the first value. In some embodiments, the integrated circuit further includes a first memory circuit coupled to the first power rail and the second power rail, and being configured to receive at least one of a first control signal, the first supply voltage or the second supply voltage. In some embodiments, the first memory circuit includes a first header circuit coupled to the second power rail, and being configured to supply the second supply voltage to at least a first node in response to the first control signal. In some embodiments, the first memory circuit further includes a first memory cell array coupled to the first header circuit by the first node, and being configured to store a first set of data, and to receive the second supply voltage from the first header circuit. In some embodiments, the integrated circuit further includes a first core circuit coupled to the first memory circuit, and being configured to receive the second supply voltage.

Another aspect of this description relates to an integrated circuit. In some embodiments, the integrated circuit includes a first power rail configured to supply a first supply voltage. In some embodiments, the integrated circuit further includes a second power rail configured to supply a second supply voltage different from the first supply voltage. In some embodiments, the integrated circuit further includes a third power rail configured to supply a third supply voltage different from the first supply voltage and the second supply voltage. In some embodiments, the integrated circuit further includes a first memory circuit coupled to the first power rail and the second power rail, and being configured to receive at least one of a first control signal, the first supply voltage or the second supply voltage. In some embodiments, the first memory circuit includes a first set of level shifter circuits coupled between the second power rail and the third power rail, and being configured to generate a first set of signals in response to a second set of signals, the first set of signals having a first voltage swing, and the second set of signals having a second voltage swing different from the first voltage swing. In some embodiments, the first memory circuit further includes a second memory circuit coupled to the first power rail and the third power rail, and being configured to receive at least one of the first control signal, the first supply voltage or the third supply voltage. In some embodiments, the integrated circuit further includes a first core circuit coupled to the first memory circuit, and being configured to receive the first supply voltage.

Still another aspect of this description relates to a method of operating an integrated circuit. In some embodiments, the method includes receiving a first supply voltage from a first power rail. In some embodiments, the method further includes setting, by a first controller, a second supply voltage of a second power rail. In some embodiments, the method further includes receiving, by a level shifter circuit, a first set of signals, the level shifter circuit being coupled between the second power rail and a third power rail, the third power rail having a third supply voltage. In some embodiments, the method further includes generating, by the level shifter circuit, a second set of signals in response to the first set of signals, the first set of signals having a first voltage swing, and the second set of signals having a second voltage swing different from the first voltage swing. In some embodiments, the method further includes setting, by a second controller, a first control signal to a first logic state or a second logic state, the second logic state being different from the first logic state. In some embodiments, the method further includes receiving, by a first power gating circuit, the third supply voltage and the first control signal, the first power gating circuit being coupled between the third power rail and a first node. In some embodiments, the method further includes disabling the first power gating circuit in response to the first logic state of the first control signal. In some embodiments, the method further includes disabling a first set of circuits in response to the first power gating circuit being disabled. In some embodiments, the method further includes causing the memory circuit to enter a power down mode.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
a first power rail configured to supply a first supply voltage;
a second power rail configured to supply a second supply voltage different from the first supply voltage, the second supply voltage having a first value or a second value different from the first value;
a first memory circuit coupled to the first power rail and the second power rail, and being configured to receive at least one of a first control signal, the first supply voltage or the second supply voltage, the first memory circuit comprising:
a first header circuit coupled to the second power rail, and being configured to supply the second supply voltage to at least a first node in response to the first control signal; and
a first memory cell array coupled to the first header circuit by the first node, and being configured to store a first set of data, and to receive the second supply voltage from the first header circuit; and
a first core circuit coupled to the first memory circuit, and being configured to receive the second supply voltage.

2. The integrated circuit of claim 1, wherein the first memory circuit further comprises:
a first bit line driver circuit coupled to the first header circuit by the first node, and being configured to receive the second supply voltage, and to generate a bit line signal.

3. The integrated circuit of claim 2, wherein the first memory circuit further comprises:
a first word line driver circuit coupled to the first header circuit by the first node, and being configured to receive the second supply voltage, and to generate a word line signal.

4. The integrated circuit of claim 3, wherein the first memory circuit further comprises:
a first sense amplifier coupled to the first header circuit by the first node, and being configured to receive the second supply voltage, and to perform a read operation of the first memory cell array in response to a sense amplifier enable signal.

5. The integrated circuit of claim 4, wherein the first memory circuit further comprises:
a first power switch coupled to the second power rail, and being configured to receive the first supply voltage, and to supply the first supply voltage to the first memory cell array in response to a write driver circuit performing a write operation of the memory cell array.

6. The integrated circuit of claim 5, wherein
the first header circuit has a first threshold voltage, and
at least one of the first memory cell array, the first bit line driver circuit, the first word line driver circuit, the first sense amplifier or the first power switch has a second threshold voltage, and the second threshold voltage is greater than the first threshold voltage.

7. The integrated circuit of claim 1, wherein
a second core circuit coupled to the first memory circuit, and being configured to receive the second supply voltage.

8. The integrated circuit of claim 7, wherein at least one of the first core circuit or the second core circuit includes a central processing unit (CPU) core, a graphics processing unit (GPU) core or a memory controller core.

9. The integrated circuit of claim 1, wherein the first header circuit comprises:
a first inverter coupled to the first power rail, and being configured to generate a second control signal in response to the first control signal, the first control signal being inverted from the second control signal; and
a second inverter coupled to the first power rail, and the first inverter, and being configured to generate a third control signal in response to the second control signal, the second control signal being inverted from the third control signal.

10. The integrated circuit of claim 9, wherein the first header circuit further comprises:
a first transistor including a first terminal configured to receive the third control signal, a second terminal of the first transistor is coupled to the first power rail, and a third terminal of the first transistor is coupled to the first node.

11. An integrated circuit, comprising:
a first power rail configured to supply a first supply voltage;
a second power rail configured to supply a second supply voltage different from the first supply voltage;
a third power rail configured to supply a third supply voltage different from the first supply voltage and the second supply voltage;
a first memory circuit coupled to the first power rail and the second power rail, and being configured to receive at least one of a first control signal, the first supply voltage or the second supply voltage, the first memory circuit comprising:
a first set of level shifter circuits coupled between the second power rail and the third power rail, and being configured to generate a first set of signals in response to a second set of signals, the first set of signals having a first voltage swing, and the second set of signals having a second voltage swing different from the first voltage swing; and
a second memory circuit coupled to the first power rail and the third power rail, and being configured to receive at least one of the first control signal, the first supply voltage or the third supply voltage; and
a first core circuit coupled to the first memory circuit, and being configured to receive the first supply voltage.

12. The integrated circuit of claim 11, wherein the second memory circuit comprises:
a first header circuit coupled to the third power rail, and being configured to supply the third supply voltage to at least a first node in response to the first control signal.

13. The integrated circuit of claim 12, wherein the second memory circuit further comprises:
a first memory cell array coupled to the first header circuit by the first node, and being configured to store a first set of data, and to receive the third supply voltage from the first header circuit.

14. The integrated circuit of claim 13, wherein the second memory circuit further comprises:
a first bit line driver circuit coupled to the first header circuit by the first node, and being configured to receive the third supply voltage, and to generate a bit line signal.

15. The integrated circuit of claim 14, wherein the second memory circuit further comprises:
a first word line driver circuit coupled to the first header circuit by the first node, and being configured to receive the third supply voltage, and to generate a word line signal.

16. The integrated circuit of claim 15, wherein the second memory circuit further comprises:
a first sense amplifier coupled to the first header circuit by the first node, and being configured to receive the third supply voltage, and to perform a read operation of the first memory cell array in response to a sense amplifier enable signal.

17. The integrated circuit of claim 16, wherein the second memory circuit further comprises:
a first power switch coupled to the second power rail, and being configured to receive the first supply voltage, and to supply the first supply voltage to the first memory cell array in response to a write driver circuit performing a write operation of the memory cell array.

18. The integrated circuit of claim 17, wherein
the first set of level shifter circuits has a first threshold voltage, and
at least one of the header circuit, the first memory cell array, the first bit line driver circuit, the first word line driver circuit, the first sense amplifier or the first power switch has a second threshold voltage, and the second threshold voltage is greater than the first threshold voltage.

19. The integrated circuit of claim 11, wherein the first memory circuit further comprises:
a second set of level shifter circuits coupled between the second power rail and the third power rail, and being configured to generate the second set of signals in response to the first set of signals.

20. A method of operating a memory circuit, the method comprising:
receiving a first supply voltage from a first power rail;
setting, by a first controller, a second supply voltage of a second power rail;
receiving, by a level shifter circuit, a first set of signals, the level shifter circuit being coupled between the second power rail and a third power rail, the third power rail having a third supply voltage;
generating, by the level shifter circuit, a second set of signals in response to the first set of signals, the first set of signals having a first voltage swing, and the second set of signals having a second voltage swing different from the first voltage swing;
setting, by a second controller, a first control signal to a first logic state or a second logic state, the second logic state being different from the first logic state;
receiving, by a first power gating circuit, the third supply voltage and the first control signal, the first power gating circuit being coupled between the third power rail and a first node;
disabling the first power gating circuit in response to the first logic state of the first control signal;
disabling a first set of circuits in response to the first power gating circuit being disabled; and
causing the memory circuit to enter a power down mode.
